(19) United States
(12) Patent Application Publication
(10) Pub. No.: US 2026/0150555 A1
(43) Pub. Date: May 28, 2026

(54) Display Device and Electronic Device Including Same

(71) Applicant: Samsung Display Co., Ltd., Yongin-si (KR)

(72) Inventors: Oh June Kwon, Yongin-si (KR); Soo Min Oh, Yongin-si (KR); Woo Yong Sung, Yongin-si (KR)

(73) Assignee: Samsung Display Co., Ltd., Yongin-si (KR)

(21) Appl. No.: 19/288,118

(22) Filed: Aug. 1, 2025

(30) Foreign Application Priority Data
Nov. 28, 2024 (KR) 10-2024-0173201

(51) Int. Cl. H10K 59/80; H10K 59/65

(52) U.S. Cl. CPC H10K 59/873; H10K 59/65

(57) ABSTRACT

Provided is a display device and an electronic device that includes the display device. A display device includes a substrate, a plurality of pixels arranged on the substrate in a display area, a through hole penetrating the substrate, a plurality of first grooves surrounding the through hole, a plurality of block structures arranged between the plurality of first grooves and the through hole, and a second groove surrounding the plurality of block structures.

### CROSS-REFERENCE TO RELATED APPLICATION

This application claims priority from Korean Patent Application No. 10-2024-0173201 filed on Nov. 28, 2024, the disclosure of which is incorporated by reference herein in its entirety.

### TECHNICAL FIELD

The present disclosure relates to a display device and an electronic device that incorporates such display device.

### BACKGROUND

With the advance of our information-oriented society, there is increasing demand for display devices that are capable of displaying images in various ways. For example, display devices may be included in various electronic devices such as smartphones, digital cameras, laptop computers, navigation devices, and smart televisions.

Many contemporary display devices include a light receiving display device such as a liquid crystal display device, a field emission display device, a light emitting display device, or the like. Light emitting display devices may be, for example, an organic light emitting display device including an organic light emitting element, an inorganic light emitting display device including an inorganic light emitting element such as an inorganic semiconductor or an ultra-small light emitting display device including an ultra-small light emitting element.

While use of the above-mentioned and other similar varieties of display device is generally desirable, existing devices may suffer from inadequate durability. Accordingly, a need exists for display devices with improved durability.

### BRIEF SUMMARY

One aspect of the present disclosure provides a display device having improved durability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

A display device according to various embodiments of the present disclosure includes a substrate, a plurality of pixels arranged on the substrate in a display area, a through hole penetrating the substrate, a plurality of first grooves surrounding the through hole, a plurality of block structures arranged between the plurality of first grooves and the through hole, and a second groove surrounding the plurality of block structures.

In some examples of the display device, each pixel of the plurality of pixels may include a first electrode, a light emitting layer arranged on the first electrode, and a second electrode arranged on the light emitting layer. In at least a subset of these examples, the second groove may include a first remnant containing the same material as the light emitting layer and a second remnant arranged on the first remnant and containing the same material as the second electrode. In some variations of the above examples of the display device, the second groove may include an encapsulation layer arranged on the second remnant. In still further examples, the encapsulation layer may include an inorganic film.

In some examples, the display device may include a first organic film arranged on the substrate, and the plurality of block structures may be arranged on the first organic film such that a first block structure of the plurality of block structures and a second block structure of the plurality of block structures are adjacent to each other along one direction. In a subset of these examples, the first block structure may include a first sub-block structure and a second sub-block structure arranged on the first sub-block structure. In another subset of these examples, the second groove is located in between the first block structure and the second block structure. In some of these examples, the second groove may include a pair of opposing surfaces and an uplift portion in between the pair of opposing surfaces. The uplift portion may have a convex curved portion with a convex surface that faces an open space defined by the second groove. In some variations, the pair of opposing surfaces may be a pair of opposing inclined surfaces. In another subset of examples of the display device, the second groove may include an encapsulation layer that includes an encapsulation inorganic film. A modulus of elasticity of the encapsulation inorganic film may be greater than a modulus of elasticity of the first block structure. Similarly, the modulus of elasticity of the encapsulation inorganic film may be greater than a modulus of elasticity of the second block structure.

In some examples of the display device, in a plan view of the substrate, the first groove may have a closed shape. In a subset of these examples, the closed shape may be curved. In another subset of these examples, the closed shape may be circular.

In some examples of the display device, the second groove may be one second groove from among a plurality of second grooves, where the plurality of second grooves are arranged such that two or more second grooves of the plurality of grooves surround each block structure of the plurality of block structures.

An electronic device according to various embodiments of the present specification includes a display device and a power module configured to supply power to the display device. The display device includes a substrate, a plurality of pixels arranged on the substrate in a display area, a through hole penetrating the substrate, a plurality of first grooves surrounding the through hole, a plurality of block structures arranged between the plurality of first grooves and the through hole, and a second groove surrounding the plurality of block structures.

A display device according to various embodiments of the present specification includes a substrate, a plurality of pixels arranged on the substrate in a display area, a through hole penetrating the substrate, a first grooves surrounding the through hole, a plurality of block structures arranged between the plurality of first grooves and the through hole, and a second groove that surrounds the plurality of block structures. The plurality of block structures include a first block structure and a second block structure. The first groove is arranged between a first dam and a second dam and has a first width. The second groove is arranged between the first block structure and the second block structure and has a second width. In this arrangement, the first width is greater than the second width. In a variation, the display device may include a plurality of first grooves that include the first groove referenced above.

In some examples, each pixel of the plurality of pixels may include a first electrode, a light emitting layer arranged on the first electrode, and a second electrode arranged on the light emitting layer. In at least a subset of these examples, the second groove may include a first remnant containing the same material as the light emitting layer and a second remnant arranged on the first remnant and containing the same material as the second electrode. In some variations of the above examples of the display device, the second groove may include an encapsulation layer arranged on the second remnant. In still further examples, the encapsulation layer may include an inorganic film.

In some examples, the display device may include a first organic film arranged on the substrate, and the plurality of block structures may be arranged on the first organic film such that a first block structure of the plurality of block structures and a second block structure of the plurality of block structures are adjacent to each other along one direction. In a subset of these examples, the first block structure may include a first sub-block structure and a second sub-block structure arranged on the first sub-block structure. In another subset of these examples, the second groove may be located between the first block structure and the second block structure. In some of these examples, the second groove may include a pair of opposing surfaces and an uplift portion in between the pair of opposing surfaces. The uplift portion may have a convex curved portion with a convex surface that faces an open space defined by the second groove. In some variations, the pair of opposing surfaces may be a pair of opposing inclined surfaces. In another subset of examples of the display device, the second groove may include an encapsulation layer that includes an encapsulation inorganic film. A modulus of elasticity of the encapsulation inorganic film may be greater than a modulus of elasticity of the first block structure. Similarly, the modulus of elasticity of the encapsulation inorganic film may be greater than a modulus of elasticity of the second block structure.

In some examples, in a plan view of the substrate, the first groove may have a closed shape. In a subset of these examples, the closed shape may be curved. In another subset of these examples, the closed shape may be circular.

An electronic device according to various embodiments of the present specification includes a display device and a power module configured to supply power to the display device. The display device includes a substrate, a plurality of pixels arranged on the substrate in a display area, a through hole penetrating the substrate, a first groove surrounding the through hole, a plurality of block structures arranged between the plurality of first grooves and the through hole, and a second groove surrounding the plurality of block structures. The plurality of block structures include a first block structure and a second block structure. The first groove is arranged between a first dam and a second dam and has a first width. The second groove is arranged between the first block structure and the second block structure and has a second width. Additionally, the first width is greater than the second width. In a variation, the display device of the electronic device may include a plurality of first grooves that include the first groove referenced above.

According to the present disclosure, damage due to peeling of a protective film from a display device may be prevented by arranging a block structure surrounded by a groove, where the groove has a relatively narrow width, at a location adjacent to a through hole in the display device.

### BRIEF DESCRIPTION OF THE DRAWINGS

The above and other aspects and features of the present disclosure will become more apparent by reading the following detailed description of non-limiting embodiments thereof, and with reference to the accompanying drawings, in which:

FIG. 1 is a plan view illustrating a display panel and a driving integrated circuit according to one embodiment of the present disclosure;

FIG. 2 is a cross-sectional view showing an example of a display device with a bent circuit board according to one embodiment of the present disclosure;

FIG. 3 is a cross-sectional view illustrating an example of a display area of a display panel according to one embodiment of the present disclosure;

FIGS. 4 and 5 are cross-sectional views illustrating one process step of a manufacturing process to manufacture a display device according to one embodiment of the present disclosure;

FIG. 6 is a cross-sectional view schematically showing a portion of a display device according to one embodiment of the present disclosure;

FIG. 7 is a close-up view of area I of FIG. 1;

FIG. 8 is a close-up view of area J of FIG. 7;

FIG. 9 is a close-up view of area K of FIG. 8;

FIG. 10 is a cross-sectional view illustrating an example of a display panel taken along line X-X′ of FIG. 9;

FIG. 11 is a close-up view of area L of FIG. 8;

FIG. 12 is a cross-sectional view illustrating an example of a display panel taken along line Y-Y′ of FIG. 11;

FIG. 13 is a close-up view of area N of FIG. 12 according to one example;

FIGS. 14 and 15 are respective close-up views of area N of FIG. 12 according to examples that are modified with respect to FIG. 13;

FIG. 16 is a close-up of area M of FIG. 8 according to one example;

FIGS. 17, 18, 19, 20, 21 and 22 are respective close-up views of area M of FIG. 8 according to examples that are modified with respect to FIG. 16;

FIGS. 23, 24, 25 and 26 are cross-sectional views showing a process of fixing a block structure according to one embodiment of the present disclosure;

FIG. 27 is a block diagram of an electronic device according to one embodiment of the present disclosure; and

FIG. 28 is schematic views of various electronic devices according to various embodiments of the present disclosure.

### DETAILED DESCRIPTION

The advantages and features of the embodiments disclosed herein, and methods of achieving them, will become apparent upon reference to the embodiments described in detail herein in conjunction with the accompanying drawings. However, the present disclosure is not limited to the example embodiments disclosed herein and may be implemented in many ways. The example embodiments are provided for illustrative purposes and for fully conveying the scope of the disclosure to those skilled in the art.

As used herein, the terms “substantially,” “generally,” “approximately,” and “about” are intended to mean that slight deviations from absolute are included within the scope of the term so modified. References to an element or layer as being “on” another element or layer include examples in which an element or layer is directly one the other element or layer, or examples where intervening layers may also be present. Throughout the present disclosure, like reference numerals refer to like elements. The shapes, sizes, proportions, angles, numbers, etc. disclosed in the drawings to illustrate embodiments are exemplary and are not intended to be limiting to those shown.

Although terms such as first, second, and the like are used to describe various components of the present disclosure, the components are not limited by these terms. Rather, these terms are used merely to distinguish one component from another. Thus, a first component referred to herein may, in some examples, be a second component within the technical scope of the present disclosure.

Each of the features of the various embodiments disclosed herein may be combined or combinable with each other, in part or in whole, and may be technically interlocked and operated in a variety of ways. Further, each embodiment may be practiced independently of or in conjunction with one or more other embodiments contemplated herein.

Hereafter, examples of embodiments of the present disclosure will be described in detail with reference to the accompanying drawings.

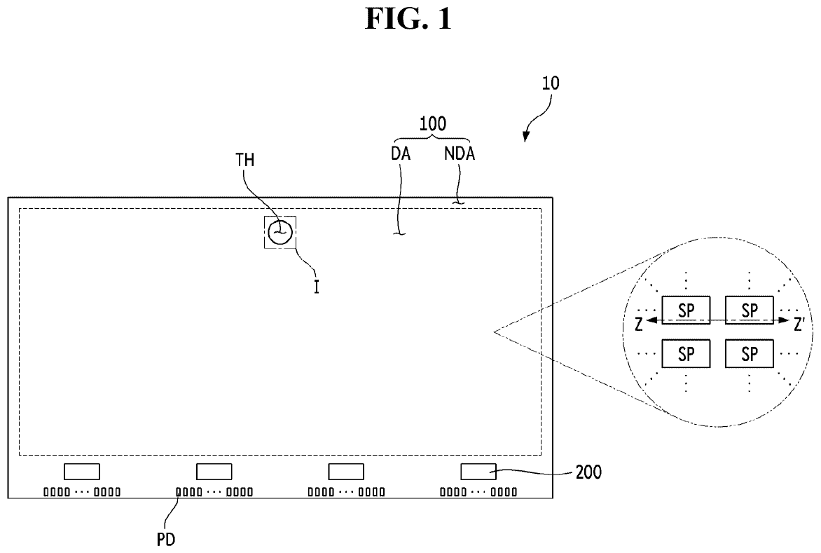

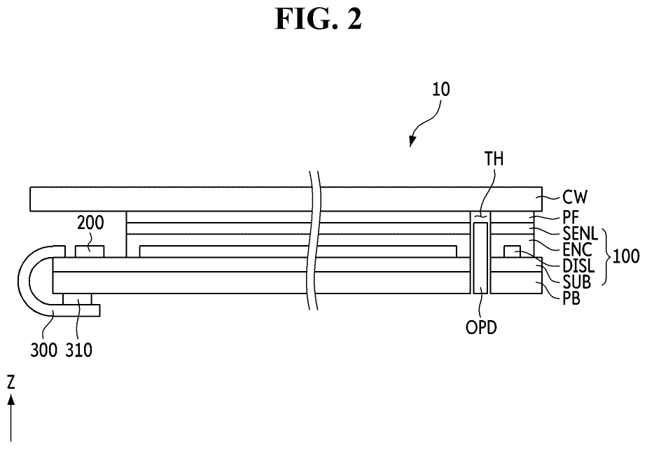

FIG. 1 is a plan view illustrating a display panel and a driving integrated circuit (driving IC) according to one embodiment of the present disclosure. FIG. 2 is a cross-sectional view of a display device according to one example that includes a bent circuit board

Referring to FIGS. 1 and 2, a through hole TH may be formed in a display device 10 according to one embodiment of the present disclosure. The through hole TH may be a hole capable of transmitting light, and may penetrate a substrate SUB, a thin film transistor layer TFTL, an encapsulation layer ENC, and a sensor electrode layer SENL of the display panel 100. The through hole TH may be a physical hole penetrating not only a display panel 100 but also a panel lower cover PB and a polarizing film PF. However, the embodiments contemplated by the present disclosure are not limited thereto, and in some embodiments, the through hole TH may penetrate the panel lower cover PB but not the display panel 100 and the polarizing film PF. As shown in FIG. 2, the cover window CW may be disposed to cover the through hole TH.

According to some embodiments, and as shown in FIG. 2, an electronic device that includes the display device 10 may further include an optical device OPD disposed in the through hole TH. The electronic device according to one embodiment may be a portable electronic device such as a mobile phone, a smart phone, a tablet personal computer (PC), a smart watch, a watch phone, a mobile communication terminal, an electronic notebook, an electronic book, a portable multimedia player (PMP), a navigation device, or an ultra mobile PC (UMPC), as well as a television, a laptop computer, a monitor, a billboard, or an Internet of Things (IOT) device. However, the embodiments of the present disclosure are not limited thereto.

The optical device OPD may be spaced apart from the display panel 100, the panel lower cover PB, and the polarizing film PF. The optical device OPD may be an optical sensor that senses light incident through the through hole TH, where the optical sensor may be, for example, a proximity sensor, an illuminance sensor, or a camera sensor.

Referring to FIG. 2, the display device 10 according to one embodiment of the present disclosure may include the display panel 100, a polarizing film PF, a cover window CW, and a panel lower cover PB. The display panel 100 may include the substrate SUB, a display layer DISL, the encapsulation layer ENC, and the sensor electrode layer SENL.

In some embodiments, the substrate SUB may be made of a hard material. For example, the substrate SUB may be made of glass. In some examples, the substrate SUB may be formed of ultra thin glass (UTG) having a thickness of approximately 200 μm or less. In some embodiments, the substrate SUB may be made of a flexible material. For example, the substrate SUB may be formed of polyimide.

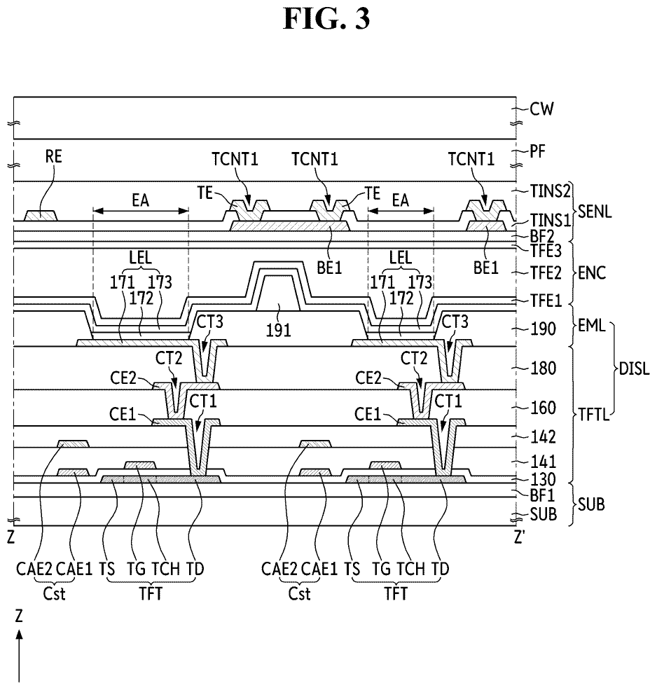

The display layer DISL may be disposed on the first surface of the substrate SUB. The display layer DISL may be a layer displaying an image. As shown in FIG. 3, the display layer DISL may include the thin film transistor layer TFTL in which thin film transistors are formed, and a light emitting element layer EML in which light emitting elements emitting light are disposed in emission areas.

In the display area DA of the display layer DISL, scan lines, data lines, power lines, or the like may be disposed so that the emission areas may emit light. In the non-display area NDA of the display layer DISL, a scan driving circuit unit outputting scan signals to the scan lines, fan-out lines connecting the data lines and the driving IC 200, and the like may be disposed.

The encapsulation layer ENC may prevent oxygen and/or moisture from permeating into the light emitting element layer EML of the display layer DISL. The encapsulation layer ENCL may be a layer for encapsulating the light emitting element layer EML of the display layer DISL. The encapsulation layer ENC may be disposed on the display layer DISL. In some examples, the encapsulation layer ENC may be disposed on the top surfaces and the side surfaces of the display layer DISL. The encapsulation layer ENC may be disposed to cover the display layer DISL.

The sensor electrode layer SENL may be disposed on the display layer DISL. The sensor electrode layer SENL may include sensor electrodes. The sensor electrode layer SENL may sense a user's touch through the inclusion of sensor electrodes.

The polarizing film PF may be disposed on the display panel 100 to reduce reflection of external light. The polarizing film PF may include a first base member, a linear polarization plate, a phase retardation film such as a quarter-wave plate (λ/4 plate), and a second base member. The first base member, the phase retardation film, the linear polarization plate, and the second base member of the polarizing film PF may be sequentially stacked on the display panel 100.

The cover window CW may be disposed on the polarizing film PF. The cover window CW may be attached onto the polarizing film PF by a transparent adhesive member such as an optically clear adhesive (OCA) film.

The panel lower cover PB may be disposed on a second surface of the substrate SUB of the display panel 100. The second surface of the substrate SUB may be a surface opposite to the first surface. The panel lower cover PB may be attached to the second surface of the substrate SUB of the display panel 100 through an adhesive member. The adhesive member may be a pressure sensitive adhesive (PSA).

The panel lower cover PB may include one or more of a light blocking member for absorbing light incident from the outside, a buffer member for absorbing an impact from the outside, and a heat dissipation member for efficiently dissipating heat from the display panel 100.

The light blocking member may be disposed under the display panel 100. The light blocking member may block light transmission, thereby preventing components (e.g., the circuit board 300 and the like) disposed under the light blocking member from being viewed from the top of the display panel 100. The light blocking member may include a light absorbing material such as a black pigment, black dyes or the like.

The buffer member may be disposed under the light blocking member. The buffer member may absorb an external impact to prevent the display panel 100 from being damaged. The buffer member may be formed of a single layer or multiple layers. For example, the buffer member may be formed of a polymer resin such as polyurethane (PU), polycarbonate (PC), polypropylene (PP), or polyethylene (PE) or may include an elastic material such as a foamed sponge obtained from rubber, a urethane-based material, or an acrylic material.

The heat dissipation member may be disposed under the buffer member. The heat dissipation member may include a first heat dissipation layer containing graphite, carbon nanotubes or the like, and a second heat dissipation layer formed of a metal thin film containing, for example, copper, nickel, ferrite, or silver which can shield electromagnetic waves and has excellent thermal conductivity.

As shown in FIG. 2, the circuit board 300, disposed on the substrate SUB at one end, may be bent toward the bottom of the display panel 100. The circuit board 300 may be attached to the bottom surface of the panel lower cover PB by an adhesive member 310. The adhesive member 310 may be a pressure sensitive adhesive.

FIG. 3 is a cross-sectional view illustrating an example of a display area of a display panel according to one embodiment of the present disclosure. The view in FIG. 3 is based on a cross-section taken along line Z-Z′ of FIG. 1.

Referring to FIG. 3, the display panel 100 according to one embodiment of the present disclosure may be an organic light emitting display panel having a light emitting element LEL including an organic light emitting layer 172.

The display layer DISL may include the thin film transistor layer TFTL including a plurality of thin film transistors and the light emitting element layer EML including a plurality of light emitting elements.

A first buffer film BF1 may be disposed on the substrate SUB. The first buffer film BF1 may be formed of an inorganic material such as one of a silicon nitride layer, a silicon oxynitride layer, a silicon oxide layer, a titanium oxide layer and an aluminum oxide layer. Alternatively, the first buffer film BF1 may be formed as a multilayer structure that includes a plurality of layers including a silicon nitride layer, a silicon oxynitride layer, a silicon oxide layer, a titanium oxide layer and an aluminum oxide layer alternately stacked with respect to each other. In variations, other combinations of two or more of the mentioned compositions may be included in a plurality of layers of a multilayer structure.

An active layer including a channel region TCH, a source region TS, and a drain region TD of the thin film transistor TFT may be disposed on the first buffer film BF1. The active layer may be formed of polycrystalline silicon, monocrystalline silicon, low-temperature polycrystalline silicon, amorphous silicon, or an oxide semiconductor material. When the active layer includes polycrystalline silicon or an oxide semiconductor material, the source region TS and the drain region TD of the active layer may be conductive regions doped with ions or impurities and having conductivity.

The gate insulating film 130 may be disposed on the active layer of the thin film transistor TFT. The gate insulating film 130 may be formed of an inorganic film, for example, a silicon nitride layer, a silicon oxynitride layer, a silicon oxide layer, a titanium oxide layer, or an aluminum oxide layer.

A first gate metal layer including a gate electrode TG of the thin film transistor TFT, a first capacitor electrode CAE1 of a capacitor Cst, and scan lines may be disposed on the gate insulating film 130. The gate electrode TG of the thin film transistor TFT may overlap the channel region TCH in the third direction (e.g., Z-axis direction). The first gate metal layer may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

A first interlayer insulating film 141 may be disposed on the first gate metal layer. The first interlayer insulating film 141 may be formed of an inorganic film, for example, a silicon nitride layer, a silicon oxynitride layer, a silicon oxide layer, a titanium oxide layer, or an aluminum oxide layer. The first interlayer insulating film 141 may include a plurality of inorganic films.

A second gate metal layer including a second capacitor electrode CAE2 of the capacitor Cst may be disposed on the first interlayer insulating film 141. The second capacitor electrode CAE2 may overlap the first capacitor electrode CAE1 in the third direction (e.g., Z-axis direction). Therefore, the capacitor Cst may be formed by the first capacitor electrode CAE1, the second capacitor electrode CAE2, and an inorganic insulating dielectric layer disposed therebetween to serve as a dielectric layer. The second gate metal layer may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

A second interlayer insulating film 142 may be disposed on the second gate metal layer. The second interlayer insulating film 142 may be formed of an inorganic film, for example, a silicon nitride layer, a silicon oxynitride layer, a silicon oxide layer, a titanium oxide layer, or an aluminum oxide layer. The second interlayer insulating film 142 may include a plurality of inorganic films.

The first data metal layer including a first connection electrode CE1 and the data lines may be disposed on the second interlayer insulating film 142. The first connection electrode CE1 may be connected to the drain region TD through a first contact hole CT1 penetrating the gate insulating film 130, the first interlayer insulating film 141, and the second interlayer insulating film 142. The first data metal layer may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

A first organic film 160 for flattening the stepped portion due to the thin film transistors TFT may be disposed on the first connection electrode CE1. The first organic film 160 may be formed of an organic film such as acryl resin, epoxy resin, phenolic resin, polyamide resin, polyimide resin and the like.

The second data metal layer including a second connection electrode CE2 may be disposed on the first organic film 160. The second data metal layer may be connected to the first connection electrode CE1 through a second contact hole CT2 penetrating the first organic film 160. The second data metal layer may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

A second organic film 180 may be disposed on the second connection electrode CE2. The second organic film 180 may be formed of an organic film such as acryl resin, epoxy resin, phenolic resin, polyamide resin, polyimide resin and the like.

In some examples, the second data metal layer including the second connection electrode CE2 and the second organic film 180 may be omitted.

The light emitting element layer EML may be disposed on the thin film transistor layer TFTL. The light emitting element layer EML may include light emitting elements LEL and a bank 190.

Each of the light emitting elements LEL may include a pixel electrode 171, the light emitting layer 172, and a common electrode 173. Each of the emission areas EA may be an area in which the pixel electrode 171, the light emitting layer 172, and the common electrode 173 are sequentially stacked such that the holes from the pixel electrode 171 and the electrons from the common electrode 173 are combined with each other to emit light. In this case, the pixel electrode 171 may be an anode electrode, and the common electrode 173 may be a cathode electrode.

A pixel electrode layer including the pixel electrode 171 may be formed on the second organic film 180. The pixel electrode 171 may be connected to the second connection electrode CE2 through a third contact hole CT3 penetrating the second organic film 180. The pixel electrode layer may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

In a top emission structure that emits light toward the common electrode 173 with respect to the light emitting layer 172, the pixel electrode 171 may be formed of a single layer of molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and Indium Tin Oxide (ITO), or a stacked structure (ITO/APC/ITO) of APC alloy and ITO to increase the reflectivity. The APC alloy is an alloy of silver (Ag), palladium (Pd) and copper (Cu).

The bank 190 serves to define the emission areas EA of the pixels. To this end, the bank 190 may be formed to expose a partial region of the pixel electrode 171 on the second organic film 180. The bank 190 may cover the edge of the pixel electrode 171. The bank 190 may be disposed in the third contact hole CT3. Put another way, the third contact hole CT3 may be filled with the bank 190. The bank 190 may be formed of an organic film such as acryl resin, epoxy resin, phenolic resin, polyamide resin, polyimide resin and the like.

A spacer 191 may be disposed on the bank 190. The spacer 191 may serve to support a mask during a process of manufacturing the light emitting layer 172. The spacer 191 may be formed of an organic film such as acryl resin, epoxy resin, phenolic resin, polyamide resin, polyimide resin and the like.

The light emitting layer 172 may be formed on the pixel electrode 171. The light emitting layer 172 may include an organic material to emit light of a predetermined color. For example, the light emitting layer 172 may include a hole transporting layer, an organic material layer, and an electron transporting layer. The organic material layer may include a host and a dopant. The organic material layer may include a material that is configured to emit predetermined light, and may be formed using a phosphorescent material or a fluorescent material.

The common electrode 173 may be formed on the light emitting layer 172. The common electrode 173 may be formed to cover the light emitting layer 172. The common electrode 173 may be a common layer formed in common on the emission areas EA. A capping layer may be formed on the common electrode 173.

In the top emission structure, the common electrode 173 may be formed of a transparent conductive material (TCO) such as ITO or Indium Zinc Oxide (IZO) capable of transmitting light or a semi-transmissive conductive material such as magnesium (Mg), silver (Ag), or an alloy of magnesium (Mg) and silver (Ag). When the common electrode 173 is formed of a semi-transmissive conductive material, the light emission efficiency can be increased due to a micro-cavity effect.

The encapsulation layer ENC may be formed on the light emitting element layer EML. The encapsulation layer ENC may include at least one inorganic film TFE1 and TFE3 to prevent oxygen or moisture from permeating into the light emitting element layer EML. In addition, the encapsulation layer ENC may include at least one organic film to protect the light emitting element layer EML from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be disposed on the common electrode 173, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may each be formed of multiple films in which one or more inorganic films of a silicon nitride layer, a silicon oxynitride layer, a silicon oxide layer, a titanium oxide layer and an aluminum oxide layer are alternately stacked. In other examples, multiple film configurations may include other arrangements of compositions including one or more of the above-mentioned compositions. The encapsulation organic film TFE2 may be an organic film such as acryl resin, epoxy resin, phenolic resin, polyamide resin, polyimide resin or the like.

The sensor electrode layer SENL is disposed on the encapsulation layer ENC. The sensor electrode layer SENL may include sensor electrodes TE and RE.

The second buffer film BF2 may be disposed on the encapsulation layer ENC. The second buffer film BF2 may include at least one inorganic film. For example, the second buffer film BF2 may be formed of multiple films in which one or more inorganic films of a silicon nitride layer, a silicon oxynitride layer, a silicon oxide layer, a titanium oxide layer and an aluminum oxide layer are alternately stacked. In other examples, multiple film configurations may include other arrangements of compositions including one or more of the above-mentioned compositions. In some examples, the second buffer film BF2 may be omitted.

The first connection portions BE1 may be disposed on the second buffer film BF2. The first connection portions BE1 may be formed of a single layer containing molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and indium tin oxide (ITO), an Ag—Pd—Cu (APC) alloy, or a stacked structure (ITO/APC/ITO) of APC alloy and ITO.

The first sensor insulating film TINS1 may be disposed on the first connection portions BE1. The first sensor insulating film TINS1 may be formed of an inorganic film, for example, a silicon nitride layer, a silicon oxynitride layer, a silicon oxide layer, a titanium oxide layer, or an aluminum oxide layer.

The sensor electrodes, that is, the driving electrodes TE and the sensing electrodes RE may be disposed on the first sensor insulating film TNIS1. In addition, dummy patterns may be disposed on the first sensor insulating film TNIS1. The driving electrodes TE, the sensing electrodes RE, and the dummy patterns do not overlap the emission areas EA. The driving electrodes TE, the sensing electrodes RE, and the dummy patterns may be formed of a single layer containing molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and indium tin oxide (ITO), an Ag—Pd—Cu (APC) alloy, or a stacked structure (ITO/APC/ITO) of APC alloy and ITO.

The second sensor insulating film TINS2 may be disposed on the driving electrodes TE, the sensing electrodes RE, and the dummy patterns. The second sensor insulating film TINS2 may include at least one of an inorganic film or an organic film. The inorganic film may be a silicon nitride layer, a silicon oxynitride layer, a silicon oxide layer, a titanium oxide layer, or an aluminum oxide layer. The organic film may include acryl resin, epoxy resin, phenolic resin, polyamide resin, or polyimide resin.

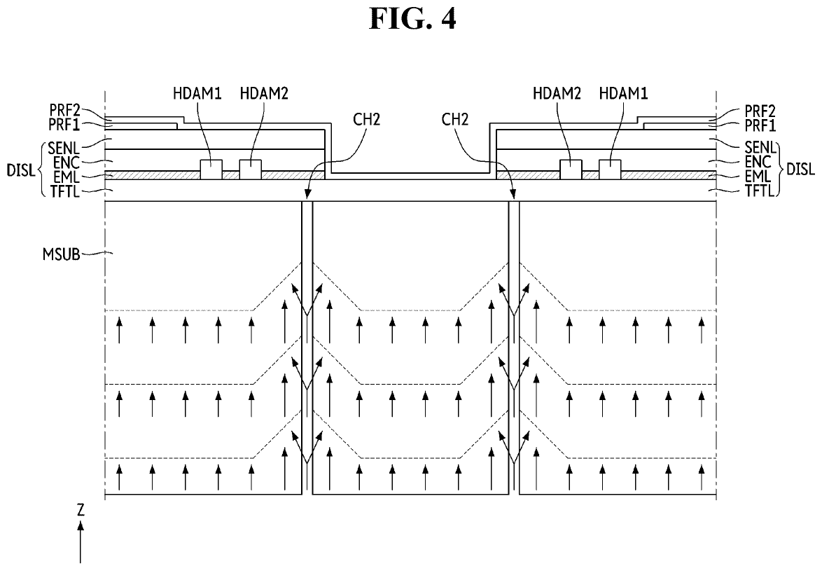

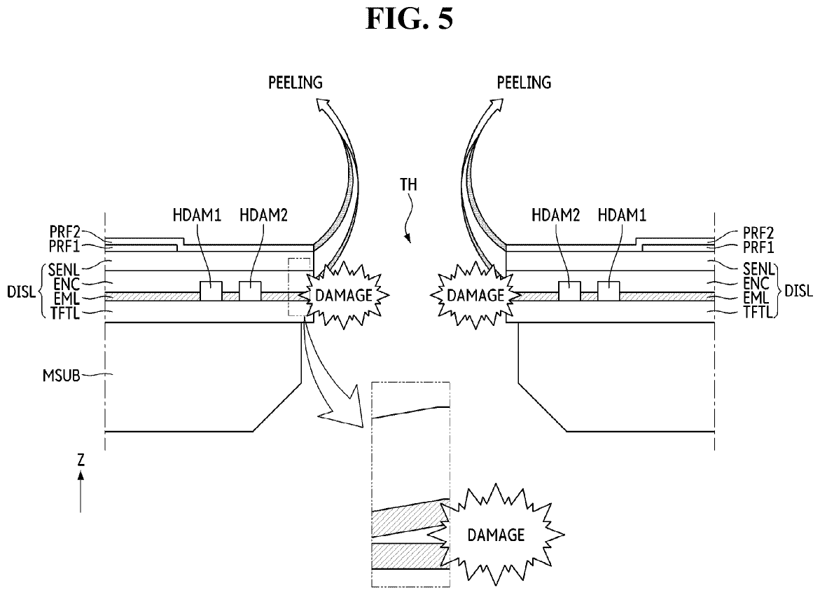

FIGS. 4 and 5 are cross-sectional views illustrating one sub-process of a process of manufacturing a display device according to one embodiment of the present disclosure. In some examples, the process of manufacturing may include a plurality of steps.

In one step, a plurality of display cells may be formed on a first surface of a mother substrate MSUB.

In a subsequent step, a plurality of first protective films PRF1 may be attached onto the plurality of display cells. Each of the plurality of first protective films PRF1 may be a buffer film for protecting the plurality of display cells from external impact. In some examples, the plurality of first protective films PRF1 may be made of a transparent material. Further, in some examples, the plurality of display cells may be inspected.

In a subsequent step, a first laser may be irradiated on a second surface facing the first surface of the mother substrate MSUB. A plurality of first laser irradiation areas disposed along the edges of the plurality of display cells may be formed. Various lasers may be used as the laser according to some embodiments.

The laser for forming the first laser irradiation areas may be irradiated with a repetition rate within a range of 10 kHz to 250 kHz, a processing speed within a range of 10 mm/s to 250 mm/s, and pulse energy within a range of 10 uJ to 300 uJ. However, in order for the laser to have a depth of approximately 225 μm from the first surface of the mother substrate MSUB, it may be preferable to perform irradiation with a repetition rate within a range of approximately 17.5 kHz to 125 kHz, a processing speed within a range of 17.5 mm/s to 125 mm/s, and pulse energy within a range of 25 uJ to 178 uJ.

In a subsequent step, a second laser may be irradiated on the second surface of the mother substrate MSUB. A plurality of second laser irradiation areas CH2 for forming a through hole in each display cell of the plurality of display cells may be formed. In one embodiment, the first laser and the second laser may be irradiated simultaneously by a plurality of laser devices in order to shorten a process time.

A second cutting line may be defined as an imaginary line that connects the plurality of second laser irradiation areas CH2 in plan view. The second cutting line may be formed by irradiating the second laser to form the plurality of second laser irradiation areas CH2 along the edge of the through hole TH. The second cutting line may depend on the form and/or shape of the through hole. For example, when the through hole TH has a circular shape in plan view, the second cutting line may be formed in a circular shape.

Although various lasers may be used as the first laser and the second laser according to the embodiments contemplated by the present disclosure, a case in which the first laser and the second laser are infrared Bessel beams having a wavelength of approximately 1030 nm is illustrated in the figures of the present disclosure.

The depth of each of the plurality of first laser irradiation areas formed by the first laser and the depth (or sketch length) of each of the plurality of second laser irradiation areas CH2 formed by the second laser may be different. The depth of the first laser irradiation area may be defined as the depth (or sketch length) of the first laser irradiation area, and the depth of the second laser irradiation area CH2 may be defined as the depth (or sketch length) of the second laser irradiation area CH2.

In a subsequent step, and with reference to FIG. 4, a second protective film PRF2 may be attached on each film of the plurality of first protective films PRF1.

The second protective film PRF2 may be attached to each film of the plurality of first protective films PRF1 and the exposed mother substrate MSUB that is not covered by the plurality of first protective films PRF1. The second protective film PRF2 may cover the plurality of first laser irradiation areas and the plurality of second laser irradiation areas CH2. The second protective film PRF2 may be an acid-resistant film for protecting the plurality of display cells from the etchant in an etching process performed on the mother substrate MSUB, where the etching process may be performed in a subsequent step, as described below.

In a subsequent step, and with continued reference to FIG. 4, an etchant may be sprayed on the second surface of the mother substrate MSUB without a separate mask. Accordingly, the thickness of the mother substrate MSUB may be reduced.

Further, the mother substrate may be cut along the plurality of first laser irradiation areas and second laser irradiation areas CH2.

When the etchant is sprayed on the second surface of the mother substrate MSUB, the mother substrate MSUB may be reduced from a first thickness to a second thickness. Since the mother substrate MSUB is etched without a separate mask, the mother substrate MSUB may be uniformly etched over the entire area of the second surface of the mother substrate MSUB.

Each second laser irradiation area of the plurality of second laser irradiation areas CH2 may include a physical hole formed by the second laser and an area around the physical hole having physical properties that are changed by the laser. Alternatively, each second laser irradiation area of the plurality of second laser irradiation areas CH2 may be an area having physical properties that are changed by the second laser without forming a physical hole. Accordingly, the etching rate by the etchant in each second laser irradiation area of the plurality of second laser irradiation areas CH2 may be higher than the etching rate in other areas of the mother substrate MSUB to which the laser is not irradiated.

Since the depth of each second laser irradiation area of the plurality of second laser irradiation areas CH2 is greater than the depth of each first laser irradiation area of the plurality of first laser irradiation areas, the etchant may permeate into the plurality of second laser irradiation areas CH2 before it permeates into the plurality of first laser irradiation areas. That is, since the plurality of second laser irradiation areas CH2 are etched along with the progress of slimming in which the thickness of the mother substrate MSUB is reduced by the etchant, a tapered cross-section may be formed on the substrate SUB by isotropic etching in the through hole TH formed by the second laser irradiation area CH2. In contrast, the plurality of first laser irradiation areas may remain unaffected by any etching, i.e., may not be etched when the slimming of the mother substrate MSUB progresses.

In a subsequent step, referring to FIG. 5, after the etching process is completed, the second protective film PRF2 may be peeled. In the process of peeling the second protective film PRF2, one side of the second protective film PRF2 that is cut may be removed. The one side may be adjacent to the through hole TH. Further, a driving IC and a circuit board are attached to each display cell of the plurality of display cells, and the first protective film PRF1 may be peeled in each display cell of the plurality of display cells.

When one side of the second protective film PRF2 is peeled, the adhesive strength between the second protective film PRF2 and the display layer DISL may affect components disposed under the second protective film PRF2. For example, the light emitting element layer EML disposed under the second protective film PRF2 may be damaged during the process of peeling the second protective film PRF2 disposed thereabove. The length of the light emitting element layer EML in a thickness direction (e.g., Z-axis direction) may be less than a length of other components SENL and ENC in the thickness direction. For example, the light emitting layer disposed in the light emitting element layer EML may be very thin. Therefore, damage due to the force necessary to overcome the adhesive strength of the second protective film PRF2 in order to peel it may occur relatively frequently.

Referring to the enlarged view included in FIG. 5, when one side of the light emitting element layer EML is separated into an upper part and a lower part, one sides of the sensor electrode layer SENL and the encapsulation layer ENC may be lifted toward the upper side of the display device together with the upper part of the light emitting element layer EML of the separated light emitting element layer EML. As a result, a gap may form between the upper part and the lower part of the light emitting element layer EML.

When a gap forms in the light emitting element layer EML during the peeling process of the second protective film PRF2, moisture and/or oxygen may permeate into the gap, which may have an affect even on the display area. Accordingly, the durability of the display device may be diminished and otherwise lessened in such circumstances.

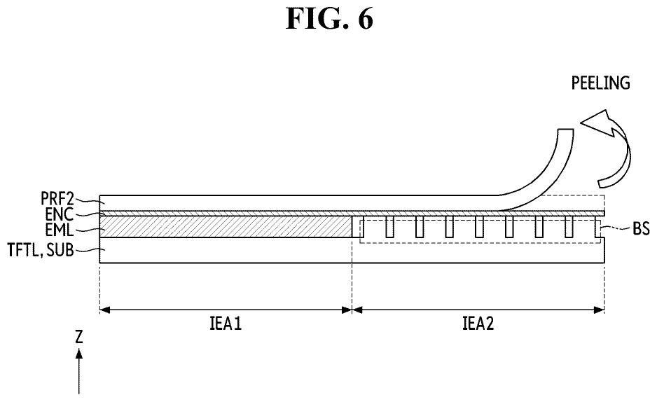

FIG. 6 is a cross-sectional view schematically showing a portion of a display device according to one embodiment of the present disclosure.

Referring to FIG. 6, a display device according to one embodiment of the present disclosure may include inorganic encapsulation areas IEA1 and IEA2. The inorganic encapsulation areas IEA1 and IEA2 may include a first inorganic encapsulation area IEA1 and a second inorganic encapsulation area IEA2. The first inorganic encapsulation area IEA1 may include the substrate SUB along with the light emitting element layer EML and the encapsulation layer ENC that are disposed on the substrate SUB. The light emitting element layer EML may include a light emitting layer. The light emitting layer, disposed in the first inorganic encapsulation area IEA1, may be arranged such that it does not actually emit light. In some examples, the light emitting layer may be a light emitting layer remnant (or first remnant) remaining in the process of arranging the light emitting layer throughout the entire display panel. The second inorganic encapsulation area IEA2 may include the substrate SUB along with a block structure BS and the encapsulation layer ENC that are disposed on the substrate SUB. The substrate SUB may be derived from the above-described mother board.

The display device according to some embodiments of the present disclosure includes the block structure BS provided in the second inorganic encapsulation area IEA2. In this manner, the influence that may be exerted on the light emitting element layer EML during the process of peeling the second protective film PRF2 may be reduced in such embodiments. For example, the block structure BS may prevent the light emitting element layer EML disposed in the first inorganic encapsulation area IEA1 from being separated by enhancing the adhesive strength between the encapsulation layer ENC and the lower arrangement components, i.e., thin film transistor layer TFTL and substrate SUB. Accordingly, moisture (or oxygen) from the outside may be prevented from permeating into the display device, and pixels disposed in the display area may be protected.

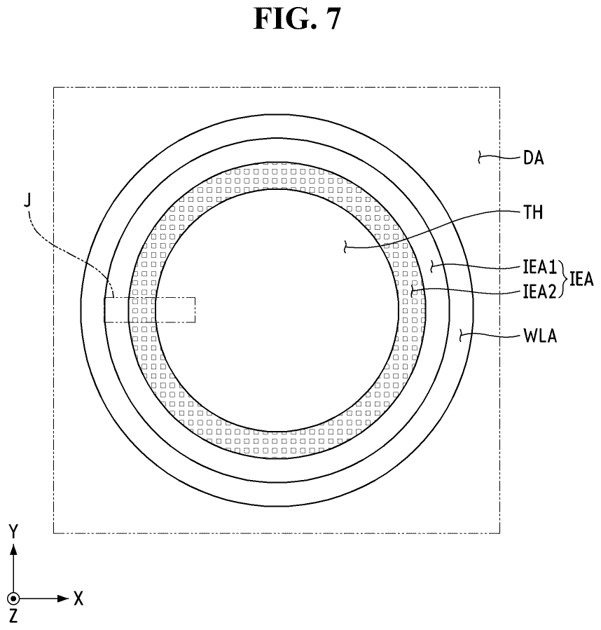

FIG. 7 is a close-up view showing area I of FIG. 1.

Referring to FIG. 7, the display panel according to some embodiments of the present disclosure may include an inorganic encapsulation area IEA surrounding the through hole TH and a wiring area WLA surrounding the inorganic encapsulation area IEA.

The inorganic encapsulation area IEA may be arranged to prevent oxygen or moisture from permeating into the light emitting element layer EML of the display layer DISL via the through hole TH. For example, the first encapsulation inorganic film TFE1 and the second encapsulation inorganic film TFE3 of the encapsulation layer ENC may be in contact with each other to prevent the permeation of oxygen or moisture.

In a display device according to some embodiments of the present disclosure, the inorganic encapsulation area IEA may include the first inorganic encapsulation area IEA1 and the second inorganic encapsulation area IEA2. The first inorganic encapsulation area IEA1 and the second inorganic encapsulation area IEA2 may correspond to the inorganic encapsulation areas IEA1 and IEA2 described in the schematic cross-section shown in FIG. 6 and described above.

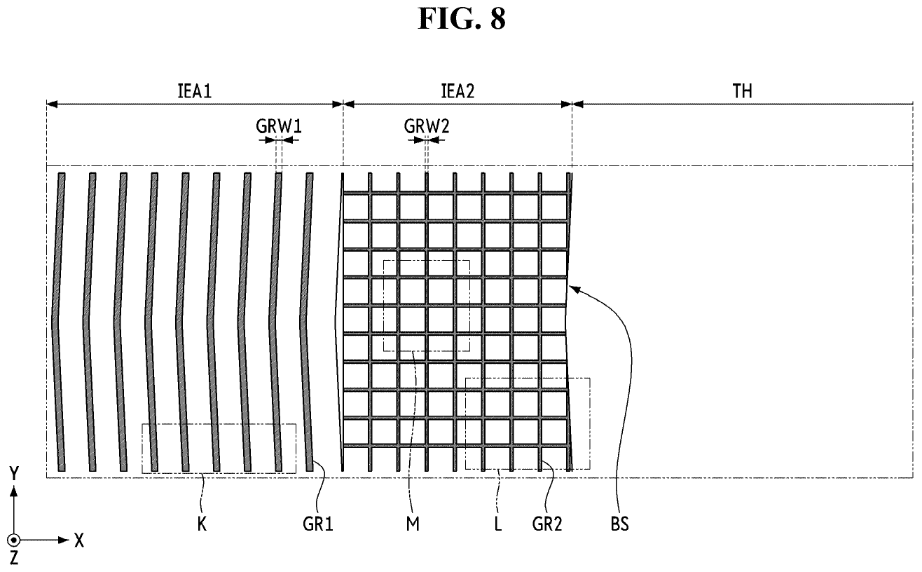

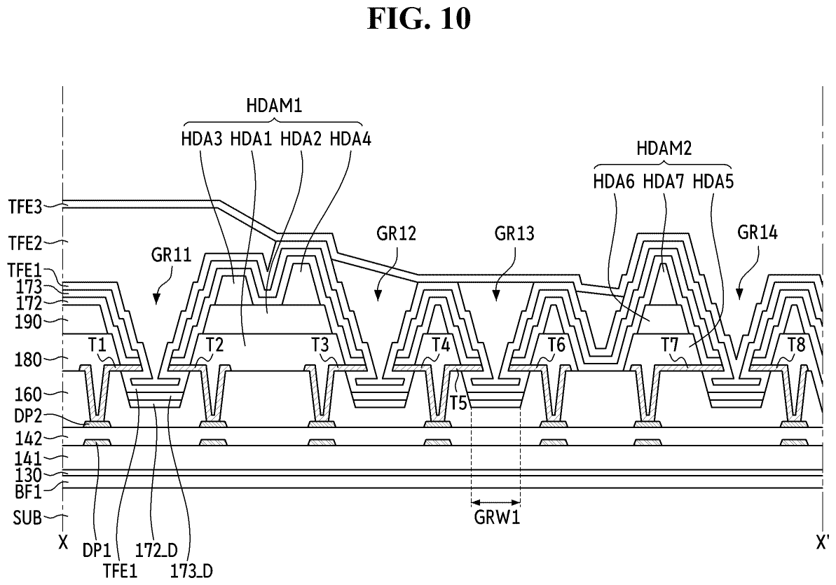

In some examples, the inorganic encapsulation area IEA may include at least one dam, at least one tip (e.g., tips T1 to T8 as shown in FIG. 10), and at least one groove (e.g., GR1 and GR2 as shown in FIG. 8).

The wiring area WLA may be an area in which bypass lines are disposed, the bypass lines being included due to the through hole TH. Some of the bypass lines may be connected to data lines, and some others of the bypass lines may be connected to a second power line to which a second source voltage higher than the first source voltage is applied. Additionally, other bypass lines may be connected to the scan lines. As shown in FIG. 7, the wiring area WLA may be surrounded by the display area DA.

FIG. 8 is a close-up view of area J of FIG. 7.

Referring to FIGS. 7 and 8, the first inorganic encapsulation area IEA1 may include a first groove GR1. The first groove GR1 may have a first width GRW1. The first groove GR1 may be formed to surround the through hole TH in a closed curve shape. In some examples, and as shown in FIG. 8, a plurality of first grooves GR1 may be formed in the first inorganic encapsulation area IEA1. Since any one first groove GR1 of the plurality of first grooves GR1 surrounds the through hole TH in a closed curve shape, e.g., closed circle, the plurality of first grooves GR1 may be arranged such that none of the first grooves GR1 include a point that intersects another first groove GR1.

With continued reference to the close-up view illustrated in FIG. 8, when the through hole TH is formed in a circular shape (circular when viewed in plan view), the enlarged view of the first groove GR1 may be approximated to a straight line. For example, the plurality of first grooves GR1 may be disposed to extend in a second direction (e.g., Y-axis direction) and may not intersect with each other. In some examples, a dam may be disposed between two first grooves of the plurality of first grooves GR1, and this will be described in detail below. In further examples, two or more dams may be disposed such that each dam separates a pair of first grooves.

The second inorganic encapsulation area IEA2 may include a second groove GR2 and the block structure BS surrounded by the second groove GR2. The second groove GR2 may have a second width GRW2. In some examples, and as shown in FIG. 8, a plurality of second grooves GR2 may be formed to intersect with each other. In some of these examples, a plurality of block structures BS may be arranged such that each block structure BS of the plurality of block structures BS is surrounded by second grooves GR2 of the plurality of second grooves GR2. The plurality of block structures BS may be disposed in the second inorganic encapsulation area IEA2, as shown in FIG. 6, for example. Accordingly, the adhesive strength between the block structures BS and the lower arrangement components (e.g., thin film transistor layer TFTL, substrate SUB) may be enhanced, and damage due to peeling of the second protective film during the manufacturing process may be prevented. In examples where an encapsulation layer ENC is disposed over the block structures BS, adhesive strength may be enhanced between the encapsulation layer ENC and the lower arrangement components.

In some embodiments, the first width GRW1 of the first groove GR1 may be greater than the second width GRW2 of the second groove GR2. Similarly, the first width GRW1 of each first groove in the plurality of first grooves GR1 may be greater than the second width GRW2 of each second groove of the plurality of second grooves GR2. In some examples, the first width GRW1 may be in a range from 20 μm to 30 μm, and the second width GRW2 may be in a range from 0.1 μm to 8 μm. Since the second width GRW2 is sufficiently small relative to the surface area of second inorganic encapsulation area IEA2, the adhesive strength between the block structure BS and the lower arrangement components may be enhanced. A process for enhancing the adhesive strength in the case where the second width GRW2 is sufficiently small is described below.

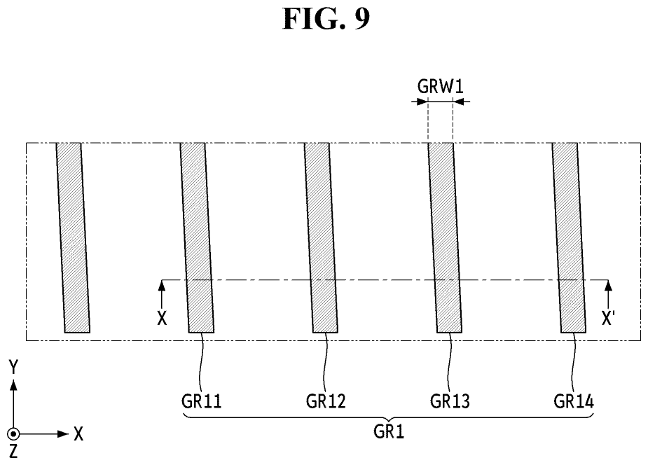

FIG. 9 is a close-up view showing area K of FIG. 8. FIG. 10 is a cross-sectional view illustrating an example of a display panel taken along line X-X′ of FIG. 9.

As shown in FIG. 10, the cross-sectional view taken along line X-X′ includes the light emitting layer 172, the common electrode 173, the second organic film 180, the bank 190, and the like. Since the enlarged area K is located between the display area and the through hole, the above-described components may be arranged in various ways other than exactly as shown in FIG. 10. However, the arrangement shown in FIG. 10 is instructive for understanding a correlation between the inorganic encapsulation area IEA1 with the above-described cross-sectional view taken along line Z-Z′ and shown in FIG. 3.

For example, to be precise, the second organic film 180 shown in the cross-sectional view may be any one sub-dam, the bank 190 may be another sub-dam, the light emitting layer 172 may be a light emitting layer remnant (or first remnant) disposed in the extended portion of the broken region without actually emitting light, and the common electrode 173 may be a common electrode remnant (or second remnant) disposed in the extended portion of the broken region without actually performing the function of an electrode.

It should be appreciated that the reference numerals in FIG. 10 are designated as illustrated in order to directly show the correlation with the light emitting element disposed in the display area as shown in the figures, and are not limiting.

Referring to FIGS. 9 and 10, in the first inorganic encapsulation area IEA1, a first dummy pattern DP1 may include the same material as the second gate metal layer including the second capacitor electrode CAE2 of the capacitor Cst and may be disposed on the same layer. For example, the first dummy pattern DP1 may be disposed on the first interlayer insulating film 141. The first dummy pattern DP1 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

A second dummy pattern DP2 may include the same material as the first data metal layer including the first connection electrode CE1 and the data lines and may be disposed on the same layer. For example, the second dummy pattern DP2 may be disposed on the second interlayer insulating film 142. The second dummy pattern DP2 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The second dummy pattern DP2 may overlap the first dummy pattern DP1 in the third direction (e.g., Z-axis direction).

The first to eighth tips T1 to T8 may include the same material as the second data metal layer including the second connection electrode CE2 and may be disposed on the same layer. For example, the first to eighth tips T1 to T8 may be disposed on the first organic film 160. The first to eighth tips T1 to T8 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

Each of the first to eighth tips T1 to T8 may be connected to the second dummy pattern DP2 through a contact hole penetrating the first organic film 160. Each of the first to eighth tips T1 to T8 may include an eaves structure in which the top surface and the bottom surface are exposed without being covered by the first organic film 160, the second organic film 180, a first dam HDAM1, and a second dam HDAM2. For example, the plurality of tips may be formed integrally, similarly to the fourth tip T4 and the fifth tip T5. Each of the first to eighth tips T1 to T8 may be a protruding pattern or a trench pattern for forming a groove (or trench).

The plurality of first grooves GR1 may be disposed in the first inorganic encapsulation area IEA1. A first-first groove GR11 may be formed between a first tip T1 and a second tip T2, a first-second groove GR12 may be formed between a third tip T3 and a fourth tip T4, a first-third groove GR13 may be formed between a fifth tip T5 and a sixth tip T6, and a first-fourth groove GR14 may be formed between a seventh tip T7 and an eighth tip T8. The first-first groove GR11 may have an eaves structure formed by the first tip T1 and the second tip T2, the first-second groove GR12 may have an eaves structure formed by the third tip T3 and the fourth tip T4, the first-third groove GR13 may have an eaves structure formed by the fifth tip T5 and the sixth tip T6, and the first-fourth groove GR14 may have an eaves structure formed by the seventh tip T7 and the eighth tip T8.

Since the light emitting layer 172 is deposited by evaporation and the common electrode 173 is deposited by sputtering, they may be disposed to be broken at each of the first-first to first-fourth grooves GR11, GR12, GR13, and GR14 because the step coverage is low. In contrast, the first encapsulation inorganic film TFE1 and the second encapsulation inorganic film TFE3 may be deposited by chemical vapor deposition, atomic layer deposition, or the like, and thus may be formed to be continuous without being broken in each of the first-first to first-fourth grooves GR11, GR13, and GR14 because the step coverage is high. Step coverage refers to the ratio of the degree of thin film coated on an inclined portion to the degree of thin film coated on a flat portion. The light emitting layer 172, a broken light emitting layer remnant 172_D, the common electrode 173, and a broken common electrode remnant 173_D may be disposed in the first-first to first-fourth grooves GR11, GR13, and GR14, respectively.

The first dam HDAM1 may include a plurality of sub-dams including first to fourth sub-dams HDA1, HDA2, HDA3, and HDA4. Although it is illustrated that the first dam HDAM1 includes only four sub-dams HDA1, HDA2, HDA3, and HDA4, the embodiments of the present disclosure are not limited thereto. For example, the first dam HDAM1 may include three sub-dams, similarly to the second dam HDAM2.

The first sub-dam HDA1 may be disposed on the first organic film 160 and may include the same material as the second organic film 180. The first sub-dam HDA1 may be disposed on the second tip T2 and the third tip T3. The second sub-dam HDA2 may be disposed on the first sub-dam HDA1 and may include the same material as the bank 190. The third sub-dam HDA3 and the fourth sub-dam HDA4 may be disposed on the second sub-dam HDA2 and may include the same material as the spacer, but the materials are not limited thereto. The thickness of the fourth sub-dam HDA4 may be greater than the thickness of the third sub-dam HDA3, but the embodiments of the present disclosure are not limited thereto.

The second dam HDAM2 may include fifth to seventh sub-dams HDA5, HDA6, and HDA7. The second dam HDAM2 may include four sub-dams similarly to the first dam HDAM1.

The fifth sub-dam HDA5 may be disposed on the first organic film 160 and may include the same material as the second organic film 180. The fifth sub-dam HDA5 may be disposed on the seventh tip T7. The sixth sub-dam HDA6 may be disposed on the fifth sub-dam HDA5 and may include the same material as the bank 190. The seventh sub-dam HDA7 may be disposed on the sixth sub-dam HDA6 and may include the same material as the spacer, but the materials are not limited thereto.

Since the light emitting layer 172 and the common electrode 173 are broken in the first-first groove GR11, first-second groove GR12, first-third groove GR13 and first-fourth groove GR14 formed by the first to eighth tips T1 to T8, respectively, it is possible to prevent the light emitting layer 172 and the common electrode 173 from being a path through which oxygen, moisture, or the like permeates.

In one embodiment, an organic planarization layer may be disposed on the encapsulation layer ENC. With the inclusion of the organic planarization layer, a polarizing film may be easily attached onto the surface of the display device via the organic planarization layer.

The organic planarization layer may be formed of an organic film such as acryl resin, epoxy resin, phenolic resin, polyamide resin, polyimide resin and the like. For example, the organic planarization layer may include the same material as the second sensor insulating film described above, and may be formed simultaneously using the same process.

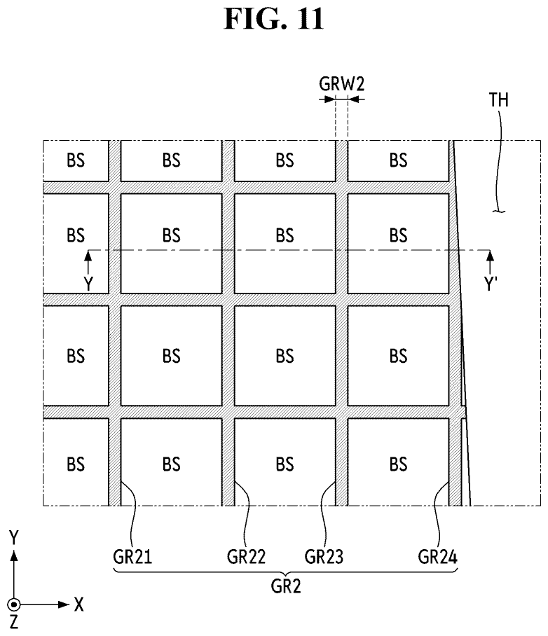

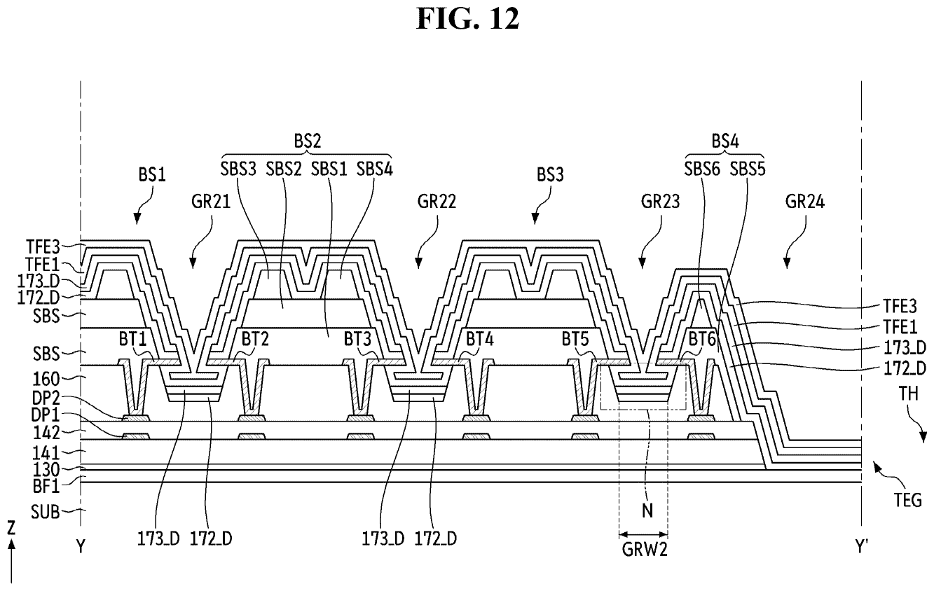

FIG. 11 is a close-up view showing area L of FIG. 8. FIG. 12 is a cross-sectional view illustrating an example of a display panel taken along line Y-Y′ of FIG. 11. Like reference numerals are given to like parts having substantially the same function as those of the above-described embodiment, and the redundant description thereof is omitted.

Referring to FIGS. 11 and 12, a plurality of block structures BS may be disposed in the second inorganic encapsulation area IEA2. Each block structure BS of the plurality of block structures may be surrounded by one or more second grooves. For example, in the example shown in FIG. 11, each block structure BS is surrounded on all four sides by second grooves GR2, one second groove on each side of the four sides. Various embodiments and modifications related to the shape of the second groove and the shape of the block structure will be described below.

With reference to FIG. 12, a first dummy pattern DP1 may include the same material as the second gate metal layer including the second capacitor electrode CAE2 of the capacitor Cst and may be disposed on the same layer. The second dummy pattern DP2 may include the same material as the first data metal layer including the first connection electrode CE1 and the data lines and may be disposed on the same layer. The second dummy pattern DP2 may overlap the first dummy pattern DP1 in the third direction (e.g., Z-axis direction).

The first to sixth block tips BT1 to BT6 may include the same material as the second data metal layer including the second connection electrode CE2 and may be disposed on the same layer. For example, the first to sixth block tips BT1 to BT6 may be disposed on the first organic film 160. Each of the first to sixth block tips BT1 to BT6 may be connected to the second dummy pattern DP2 through a contact hole penetrating the first organic film 160.

Each of the first to sixth block tips BT1 to BT6 may include an eaves structure in which top and bottom surfaces thereof are exposed without being covered by the first organic film 160, the second organic film 180, and the plurality of block structures BS2 and BS3. For example, the plurality of block tips may be formed integrally. Each of the first to sixth block tips BT1 to BT6 may be a protruding pattern or a trench pattern for forming a groove (or trench). The sixth tip BT6 may be an outermost structure adjacent to an edge TEG of the through hole TH. As illustrated, the sixth block tip BT6 is exemplified as the outermost structure adjacent to the edge TEG of the through hole TH, but the embodiments of the present disclosure are not limited thereto. For example, when the fifth block tip BT5 and the sixth block tip BT6 are omitted, the outermost structure adjacent to the edge TEG of the through hole TH may be the third block structure BS3. Alternatively, the outermost structure may be a groove (e.g., second-second groove GR22 or second-third groove GR23) for breaking the light emitting layer remnant 172_D and the common electrode remnant 173_D.

In some examples, a distance from the sixth tip BT6 to the edge TEG of the through hole TH may be approximately 300 μm.

A second-first groove GR21 may be formed between the first block tip BT1 and the second block tip BT2, the second-second groove GR22 may be formed between the third block tip BT3 and the fourth block tip BT4, the second-third groove GR23 may be formed between the fifth block tip BT5 and the sixth block tip BT6, and a second-fourth groove GR24 may be formed between the sixth block tip BT6 and the through hole TH. The second-first groove GR21 may have eaves structures formed by the first block tip BT1 and the second block tip BT2, the second-second groove GR22 may have eaves structures formed by the third block tip BT3 and the fourth block tip BT4, and the second-third groove GR23 may have eaves structures formed by the fifth block tip BT5 and the sixth block tip BT6.

Since the light emitting layer remnant 172_D is deposited by evaporation and the common electrode remnant 173_D is deposited by sputtering, they may be disposed to be broken at each of the second-first to second-third grooves GR21, GR22, and GR23 because the step coverage is low. In contrast, the first encapsulation inorganic film TFE1 and the second encapsulation inorganic film TFE3 may be deposited by chemical vapor deposition, atomic layer deposition, or the like, and thus may be formed to be continuous without being broken in each of the second-first to second-third grooves GR21, GR22, and GR23 because the step coverage is high. Step coverage refers to the ratio of the degree of thin film coated on an inclined portion to the degree of thin film coated on a flat portion. The broken light emitting layer remnant (or first remnant) 172_D and the broken common electrode remnant (or second remnant) 173_D may be disposed in each of the second-first groove GR21, second-second groove GR22, second-third groove GR23, and second-fourth groove GR24.

With continued reference to FIG. 12, the plurality of block structures BS may include first, second, third and fourth block structures BS1, BS2, BS3, and BS4. The second block structure BS2 may include a plurality of sub-block structures including first to fourth sub-block structures SBS1, SBS2, SBS3, and SBS4. Although the second block structure BS2 in the depicted embodiment includes only four sub-block structures SBS1, SBS2, SBS3, and SBS4, the embodiments of the present disclosure are not limited thereto. For example, the second block structure BS2 may include two sub-block structures, similarly to the fourth block structure BS4.

The first sub-block structure SBS1 may be disposed on the first organic film 160, and may include the same material as the second organic film. The first sub-block structure SBS1 may be disposed on the second block tip BT2 and the third block tip BT3. The second sub-block structure SBS2 may be disposed on the first sub-block structure SBS1, and may include the same material as a bank. The third sub-block structure SBS3 and the fourth sub-block structure SBS4 may be disposed on the second sub-block structure SBS2, and may include the same material as the spacer described above, but the embodiments contemplated by the present disclosure are not limited thereto. The fourth sub-block structure SBS4 may be disposed closer to the through hole TH than the third sub-block structure SBS3. The thickness of the fourth sub-block structure SBS4 may be the same as that of the third sub-block structure SBS3, but the embodiments contemplated by the present disclosure are not limited thereto.

The fourth block structure BS4 may include a plurality of sub-block structures including the fifth and sixth sub-block structures SBS5 and SBS6. Although the fourth block structure BS4 in the depicted embodiment includes only two sub-block structures SBS5 and SBS6, the embodiments contemplated by the present disclosure are not limited thereto. For example, the fourth block structure BS4 may include four sub-block structures, similarly to the second block structure BS2.

The fifth sub-block structure SBS5 may be disposed on the first organic film 160, and may include the same material as the second organic film. The fifth sub-block structure SBS5 may be disposed on the sixth block tip BT6. The sixth sub-block structure SBS6 may be disposed on the fifth sub-block structure SBS5, and may include the same material as the bank.

The second width GRW2 of the second grooves GR21, GR22, GR23, and GR24 may be determined by the width and shape of the sub-block structure included in the block structure. As described above, when the second width GRW2 is sufficiently small, the adhesive strength of the first encapsulation inorganic film TFE1 with the lower arrangement component (e.g., the first organic film 160 and the interlayer insulating films 141 and 142) may be enhanced. The process of enhancing the adhesive strength will be described below.

When the width between the block structures is sufficiently small, the encapsulation inorganic films TFE1 and TFE3 may be prevented from being separated from the lower arrangement component during the process of peeling the second protective film. Further, the components disposed in the first inorganic encapsulation area, which is a relatively lower priority during the peeling process, may remain unaffected. Accordingly, these features are advantageous in that they enhance protection of the pixels disposed in the display area.

The light emitting layer remnant 172_D, the common electrode remnant 173_D, the first encapsulation inorganic film TFE1, and the second encapsulation inorganic film TFE3 may extend to the edge TEG of the through hole TH. As shown in FIG. 12, the end of the light emitting layer remnant 172_D, the end of the common electrode remnant 173_D, the end of the first encapsulation inorganic film TFE1, or the end of the second encapsulation inorganic film TFE3 may coincide with the edge TEG of the through hole TH.

Since the light emitting layer remnant 172_D and the common electrode remnant 173_D are broken in each of the second-first groove GR21, the second-second groove GR22 and the second-third groove GR23 formed by the first to sixth block tips BT1 to BT6, the light emitting layer remnant 172_D and the common electrode remnant 173_D exposed to the through hole TH may be prevented from becoming a path for oxygen and moisture to permeate the display device.

In one embodiment, the encapsulation organic film may be absent from the second inorganic encapsulation area IEA2. In such an arrangement, the encapsulation organic film disposed in the first inorganic encapsulation area IEA1 may be prevented from overflowing toward the through hole TH due to the dam configuration of the first inorganic encapsulation area or the like. Accordingly, the encapsulation organic film according to such embodiment may only be disposed outside of the second inorganic encapsulation area.

In one embodiment, an organic planarization layer may be disposed on the encapsulation layer ENC. Due to the inclusion of the organic planarization layer, a polarizing film may be easily attached onto the encapsulation layer ENC via the organic planarization layer. The organic planarization layer may be formed of an organic film such as acryl resin, epoxy resin, phenolic resin, polyamide resin, polyimide resin and the like. For example, the organic planarization layer and the second sensor insulating film described above may include the same material, and may be formed simultaneously by the same process.

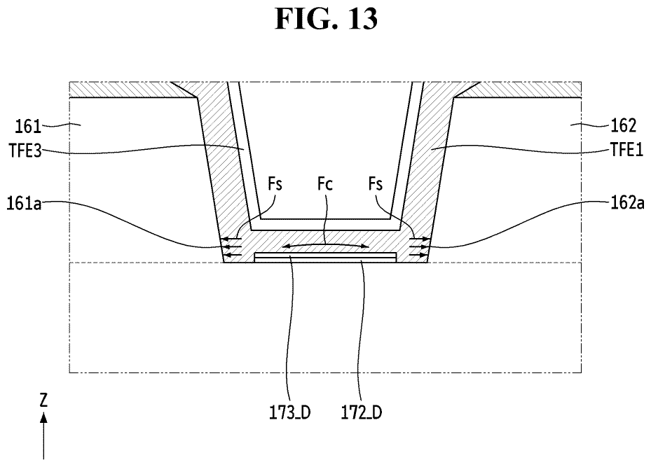

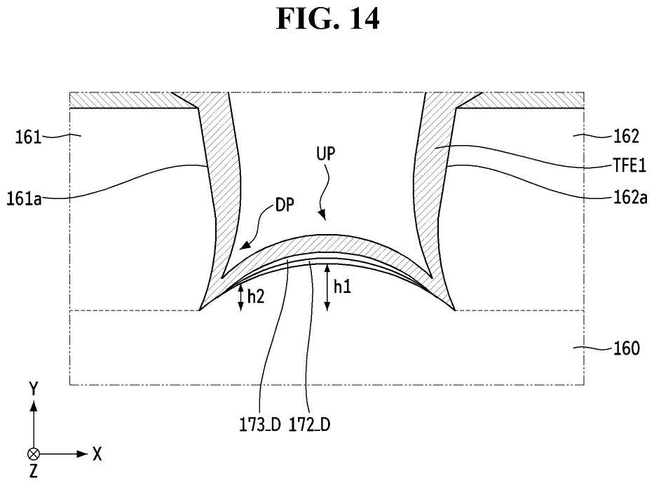

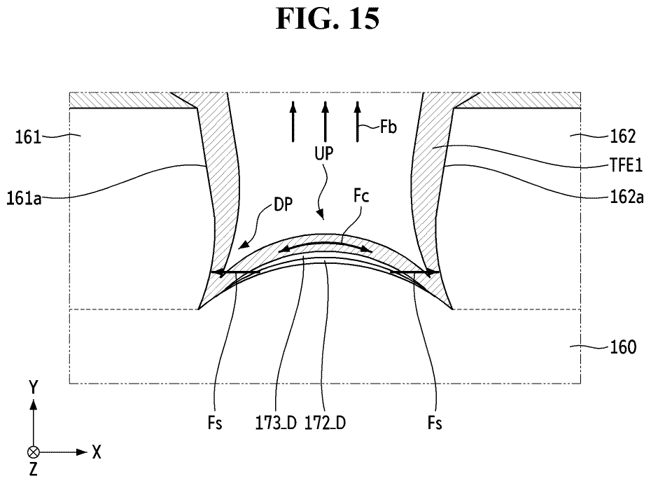

FIG. 13 is a close-up view of area N of FIG. 12 according to one example embodiment. FIGS. 14 and 15 are close-up views of area N of FIG. 12 when modified with respect to FIG. 13. The reason that the adhesive strength of the encapsulation inorganic film is enhanced with the described embodiments is set forth below.

In FIGS. 14 and 15, since the encapsulation organic film is not disposed in the second inorganic encapsulation area IEA2, the second encapsulation inorganic film may be disposed directly on the first encapsulation inorganic film TFE1. Therefore, the arrangement shape of the second encapsulation inorganic film or the like may be derived with reference to FIG. 13.

Referring to FIG. 13, a first-first organic film 161, a first-second organic film 162, and the first remnant 172_D and the second remnant 173_D disposed between the first-first organic film 161 and the first-second organic film 162 may be formed. Thereafter, the encapsulation inorganic films TFE1 and TFE3 may be deposited on the remnants 172_D and 173_D by a chemical vapor deposition (CVD) method. In this step, the encapsulation inorganic films TFE1 and TFE3 may be formed to conform to the surface shape of the remnants 172_D and 173_D, each having a thin thickness.

The encapsulation inorganic films TFE1 and TFE3 deposited on the remnants 172_D and 173_D are deposited such that they have a compressive stress, and preferably have a compressive stress value in a range from about −500 MPa to 0 MPa, but in any event, less than 0 MPa. At this time, the compressive stress acts as a force in a direction of pushing the encapsulation inorganic films TFE1 and TFE3 against the remnants 172_D, 173_D and a force Fc in a direction of bending the encapsulation inorganic films TFE1 and TFE3 downward and away from the remnants 172_D, 173_D on respective opposite sides of the remnants 172_D, 173D, as shown in FIG. 15, for example.

At a compressive stress that is outside of the corresponding numerical range, the electrical characteristics of the display device may deteriorate due to deterioration of the film quality of the film formed on the encapsulation inorganic films TFE1 and TFE3 or a dislocation phenomenon due to an excessive stress may occur at the interface between the upper portions of the encapsulation inorganic films TFE1 and TFE3 and another thin film formed thereon, and it may be difficult to form an uplift portion UP, e.g., as indicated in FIG. 14, between the first-first organic film 161 and the first-second organic film 162 only by the deposition process of the encapsulation inorganic films TFE1 and TFE3.

Further, when the moduli (e.g., moduli of elasticity) of the encapsulation inorganic films TFE1 and TFE3 are less than the modulus of the first organic film 160 including the first-first organic film 161 and the first-second organic film 162, the first organic film 160 may have a rigidity or strength greater than those of the encapsulation inorganic films TFE1 and TFE3 and, thus, it may be difficult to generate a compressive stress, a repulsive force, or an uplift only by the deposition process of the encapsulation inorganic films TFE1 and TFE3. Therefore, in such circumstances, it is necessary to adjust the modulus value such that the encapsulation inorganic films TFE1 and TFE3 have moduli greater than that of the first organic film 161 and 162. A desired compressive stress or uplift phenomenon may be implemented between the first-first organic film 161 and the first-second organic film 162 only by the deposition process of the encapsulation inorganic films TFE1 and TFE3.

When the compressive stress acts, a force (or repulsive force) that horizontally pushes as much as possible is generated between inorganic materials, and, as shown in FIG. 13, a repulsive force Fs that pushes the lower regions of the first-first organic film 161 and the first-second organic film 162, that is, the lower regions of the opposing inclined surfaces of the first-first organic film 161 and the first-second organic film 162, in the horizontal direction may be generated by the horizontal pushing force Fc at both edges of the encapsulation inorganic films TFE1 and TFE3 deposited on the remnants 172_D and 173_D.

In this way, when the repulsive force Fs that horizontally pushes the lower regions of the opposing inclined surfaces of the first-first organic film 161 and the first-second organic films 162 is generated, the adhesive strength of the encapsulation inorganic films TFE1 and TFE3 with respect to the first organic film 161 and 162 or the lower arrangement component thereof (e.g., interlayer insulating film) may be enhanced.

In one embodiment, the generation of an uplift portion may vary depending on the material of the substrate of the display device. For example, when the substrate has a hard material, only a repulsive force may be generated. In other examples, when the substrate has a flexible material, an uplift phenomenon may occur as will be described below, and an uplift portion and/or a depressed portion may be generated. Hereinafter, a case in which a substrate has a flexible material and an uplift portion and/or a depressed portion is generated will be described, but the embodiments contemplated by the present disclosure are not limited thereto.

Referring to FIG. 14, a counterclockwise torque may be generated in the lower region of the first-first organic film 161, and a clockwise torque may be generated in the lower region of the first-second organic film 162. Accordingly, the uplift portion UP may be formed.

An opposing inclined surface 161a of the first-first organic film 161 and an opposing inclined surface 162a of the first-second organic film 162 may both include a surface that is partially curved, and a portion of the first organic film in between the first-first organic film 161 and the first-second organic film 162 may include the uplift portion UP having a convex curved surface in the thickness direction (e.g., Z-axis direction).

As shown in FIG. 14, a depressed portion DP may be formed in the region where the lower region of the opposing inclined surface 161a of the first-first organic film 161 and the lower region of the opposing inclined surface 162a of the first-second organic film 162 meet the top surface of the uplift portion UP that exists between the first-first organic film 161 and the first-second organic film 162.

In one embodiment, the depressed portion DP may be defined by the opposing inclined surfaces 161a and 162a of the first organic film 161 and 162 and the top surface of the uplift portion UP. Specifically, the depressed portion DP may be formed in the region where the lower regions of the opposing inclined surfaces 161a of the first-first organic film 161 and the opposing inclined surface 162a of the first-second organic film 162 meet respective ends of the top surface of the uplift portion UP, and the depressed portion DP may include one side surface formed by the opposing inclined surfaces 161a and 162a of the first organic film 161 and 162 and the other side surface formed by the top surface of the uplift portion UP. The width between one side surface and the other side surface of the depressed portion DP may decrease from the upper region toward the lower region of the depressed portion DP, i.e., toward the substrate SUB, and one side surface and the other side surface of the depressed portion DP may overlap at the end of the depressed portion DP.

Further, the end of the depressed portion DP may be located at the same level as the top surface of the first organic film 160 located outside the first organic film 161 and 162. However, the embodiments contemplated by the present disclosure are not limited thereto.

The top surface of the uplift portion UP may be located at a position higher than the top surface of the first organic film 160 located outside the first organic film 161 and 162. Specifically, and as shown in FIG. 14, for example, the central portion of the top surface of the uplift portion UP may be located at a first height h1 with respect to the top surface of the first organic film 160 located outside the first organic film 161 and 162, and the top surface of the uplift portion UP adjacent to the depressed portion DP may be located at a second height h2. The first height h1 may be higher than the second height h2, and the first height h1 may be within a range from about 31.5 μm to about 52 μm, but the embodiments contemplated by the present disclosure are not limited thereto. The uplift portion UP may include a convex curved portion with a convex surface facing an open space defined by the second groove GR2, e.g., one of second-first through second-fourth grooves GR21, GR22, GR23, GR24.

The remnants 172_D and 173_D, the first encapsulation inorganic film TFE1, and the second encapsulation inorganic film (not shown) may be sequentially disposed on the surfaces of the first-first organic film 161, the first-second organic film 162, and the uplift portion UP and in the depressed portion DP.

The remnants 172_D and 173_D may be disposed along the surfaces of the first organic film 161 and 162 and the top surface of the uplift portion UP. At this time, the remnants 172_D and 173_D may be in direct contact with the top surface of the uplift portion UP disposed between the first-first organic film 161 and the first-second organic film 162, and the remnants 172_D and 173_D disposed on the top surface of the uplift portion UP may include a convex curved surface in the thickness direction.

The first encapsulation inorganic film TFE1 disposed on the top surface of the uplift portion UP may include the top surface in contact with the second encapsulation inorganic film (not shown) and the bottom surface in contact with the remnants 172_D and 173_D, the curvature of the top surface of the first encapsulation inorganic film TFE1 may be greater than the curvature of the bottom surface of the first encapsulation inorganic film TFE1, and the radius of curvature of the top surface of the first encapsulation inorganic film TFE1 may be less than the radius of curvature of the bottom surface of the first encapsulation inorganic film TFE1.

The first encapsulation inorganic film TFE1 may be disposed on the remnants 172_D and 173_D. Specifically, the first encapsulation inorganic film TFE1 may be disposed on the top surface of the first organic film 160 and the opposing inclined surfaces 161a and 162a.

In some embodiments, the remnants 172_D and 173_D may be absent from at least a part of the uplift portion UP and the first organic film 161 and 162. In these arrangements, the first encapsulation inorganic film TFE1 may be in direct contact with at least one of the uplift portion UP and the first organic film 161 and 162.

The second encapsulation inorganic film (not shown) may be disposed on the first encapsulation inorganic film TFE1 and may form a tip portion protruding toward the depressed portion DP in the separation space between the first-first organic film 161 and the first-second organic film 162.

Referring to FIG. 15, a behavior of the second groove in a case in which a bending stress is applied will be described in greater detail. When the bending stress is applied, a force results that peels the first encapsulation inorganic film TFE1 and the second encapsulation inorganic film (not shown) from the first organic film 161 and 162 and the uplift portion UP, and such a peeling force Fb is generally directed in the vertical direction.

The horizontal pushing force Fc is generated by the compressive force between the inorganic materials in the first encapsulation inorganic film TFE1 disposed on the top surface of the uplift portion UP, and this in turn results in the repulsive force Fs that horizontally pushes in opposite directions in the lower region between the first-first organic film 161 and the first-second organic film 162. The distance between the first organic film 161 and 162 may be sufficiently small for the compressive force to occur.

In this way, a shear force due to the strong repulsive force Fs may occur in the lower regions of the opposing inclined surfaces 161a and 162a of the respective first-first organic film 161 and the first-second organic film 162, so that the vertical peeling force Fb may be weakened. The shear force may be a resistance force to the peeling force Fb. For example, the adhesive strength of the first encapsulation inorganic film TFE1 with respect to the first organic film 160 may be enhanced by the shear force.

In one embodiment, the outer inclined surface of the first encapsulation inorganic film TFE1 disposed on the opposing inclined surfaces 161a and 162a of the first organic film 161 and 162 covers the remnants 172_D and 173_D, and the first encapsulation inorganic film TFE1, and the second encapsulation inorganic film (not shown) are located in the depressed portion DP disposed thereunder, and thus may act as a direct resistance to the peeling force Fb.

The remnants 172_D and 173_D, the first encapsulation inorganic film TFE1, and the second encapsulation inorganic film (not shown) disposed in the depressed portion DP have a width in the thickness direction that decreases toward the lower region of the depressed portion DP, i.e., in a direction toward the substrate SUB, so that the adhesive strength between the remnants 172_D and 173_D, the first encapsulation inorganic film TFE1, and the second encapsulation inorganic film (not shown) may be improved, thereby suppressing or preventing the encapsulation layer ENC from being peeled from the depressed portion DP.

As a result, the peeling force Fb may be weakened by increasing the resistance force to the peeling force Fb acting in the vertical direction, and the adhesive strength of the first encapsulation inorganic film TFE1 may be improved. Specifically, the adhesive strength between the first encapsulation inorganic film TFE1 and the remnants 172_D and 173_D and the adhesive strength between the first encapsulation inorganic film TFE1 and the second encapsulation inorganic film (not shown) may be improved.

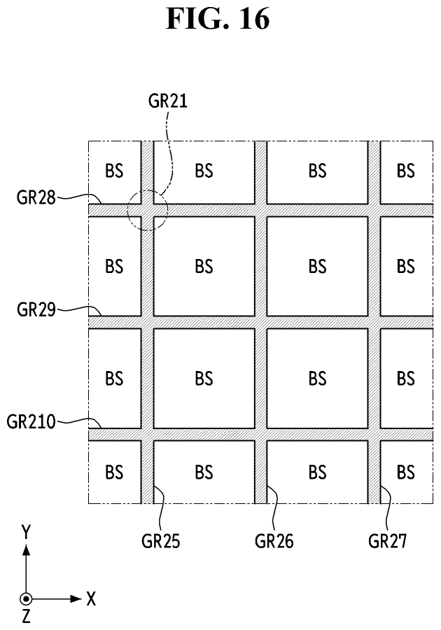

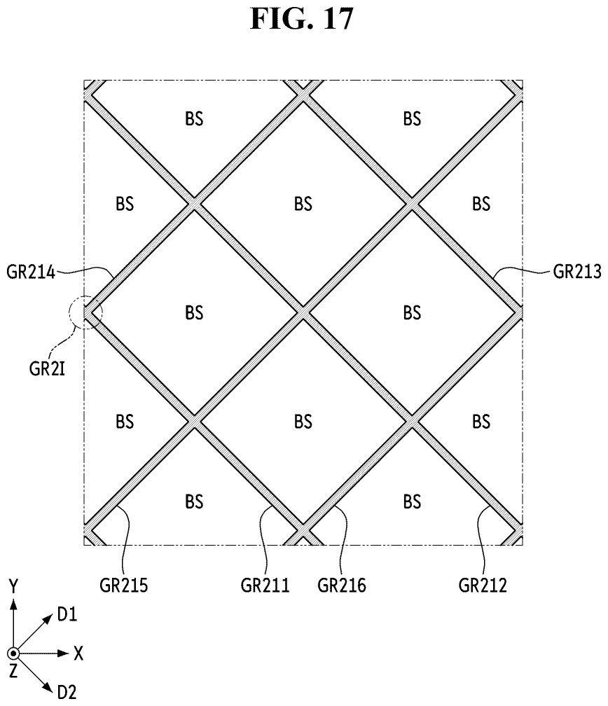

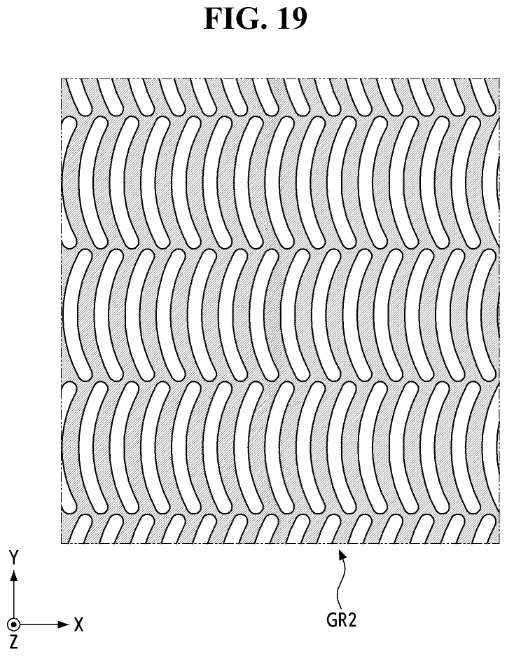

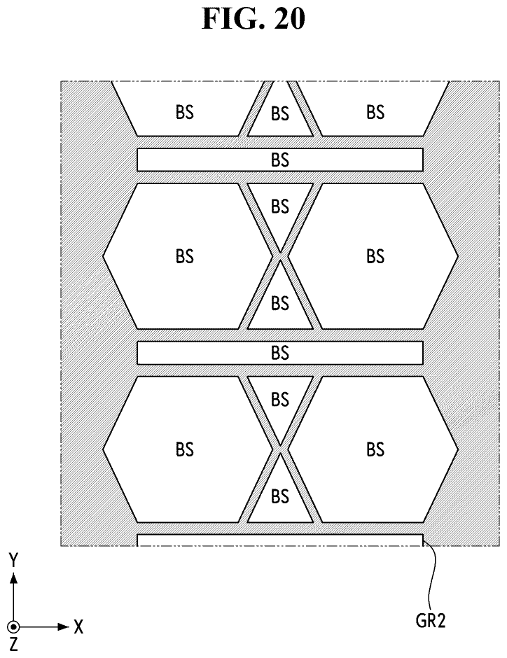

FIG. 16 is a close-up view of one example of area M of FIG. 8. FIGS. 17 to 22 are additional examples of area M of FIG. 8 that vary from the example of FIG. 16.

Referring to FIG. 16, each block structure of the plurality of block structures may be surrounded by a plurality of second grooves. In one embodiment, the plurality of second grooves may include a second-fifth groove GR25, a second-sixth groove GR26, and a second-seventh groove GR27, which are disposed to extend in the second direction (e.g., Y-axis direction), and a second-eighth groove GR28, a second-ninth groove GR29, and a second-tenth groove GR210, which are disposed to extend in the first direction (e.g., X-axis direction).

In one example of how a block structure is surrounded by a plurality of second grooves, one block structure BS may be disposed between at least a part of the second-fifth groove GR25 and at least a part of the second-sixth groove GR26, which are opposed to each other. Further, the same block structure BS may be disposed between at least a part of the second-eight groove GR28 and at least a part of the second-ninth groove GR29, which are opposed to each other. Accordingly, the block structure BS may be surrounded by the second-fifth groove GR25, the second-sixth groove GR26, the second-eight groove GR28, and the second-ninth groove GR29.

In one embodiment, since the plurality of second grooves surround each block structure of the plurality of block structures, the second-fifth groove GR25, the second-sixth groove GR26, and the second-seventh groove GR27, which are disposed to extend in the second direction (e.g., Y-axis direction), may form a second groove intersection point with the second-eighth groove GR28, the second-ninth groove GR29, and the second-tenth groove GR210, which are disposed to extend in the first direction (e.g., X-axis direction).

As described above, the first encapsulation inorganic film with an enhanced adhesive strength may be disposed in the second groove. On the assumption that the combined areas of all of the second grooves from among the plurality of second grooves in plan view are the same, as illustrated, a larger number of block structures with an enhanced adhesive strength may be included as the block structures are divided into multiple smaller pieces.

The principles of the described embodiment may be further applied as follows. As the total number of the block structures in the second inorganic encapsulation area IEA2 increases, the second width of the second groove may become smaller and the adhesive strength of the first encapsulation inorganic film may be further enhanced.

Referring to FIG. 17, a plurality of second grooves may include a second-eleventh groove GR211, a second-twelfth groove GR212, and a second-thirteenth groove GR213, which are each disposed to extend in a first-second direction D2 in the XY plane but at an angle to both the first direction (e.g., X-axis direction) and the second direction (e.g., Y-axis direction). Further, the second groove may include a second-fourteenth groove GR214, a second-fifteenth groove GR215, and a second-sixteenth groove GR216, which are disposed to extend in a first-first direction D1 that is neither the first direction nor the second direction among the directions intersecting the first-first direction.

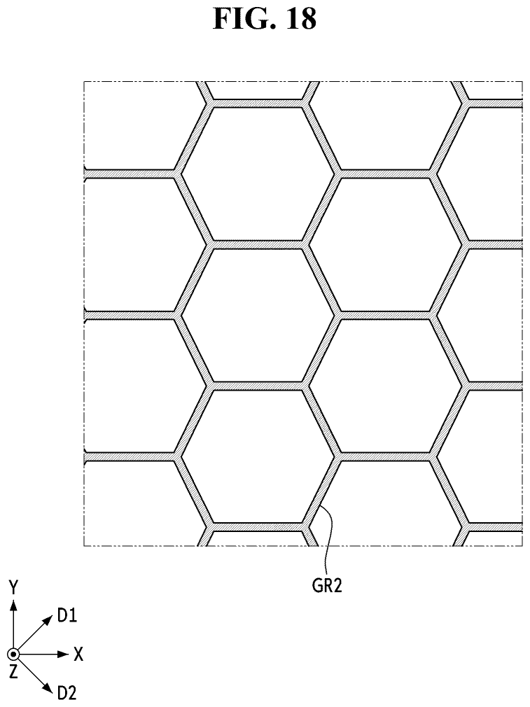

Referring to FIGS. 18 to 20, each block structure of a plurality of block structures may be formed in a hexagonal shape, a banana shape, or a combination of polygonal shapes (e.g., a triangular shape, a quadrilateral shape, a hexagonal shape, or the like). The second groove GR2 may be formed to extend in a variety of directions in the second inorganic encapsulation area IEA2.

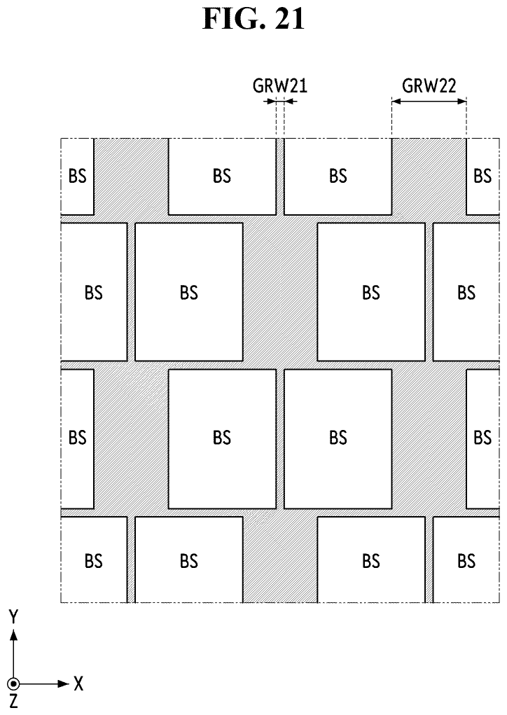

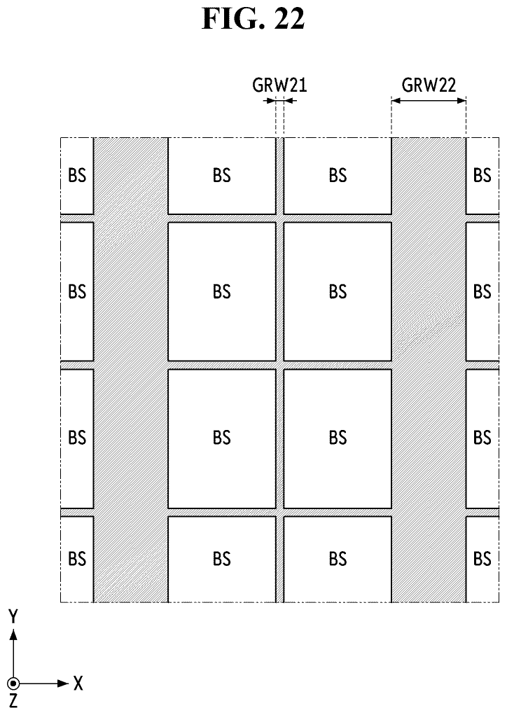

Referring to FIGS. 21 and 22, the above-described embodiments may be variously combined or modified within the scope contemplated by the present disclosure. For example, the second width of the second groove GR2 surrounding one or more of the block structures BS may vary around single block structures BS or between different block structures BS. The second width may include a second-first width GRW21 that is small relative to a second-second width GRW22. In some embodiments that include varying widths of the second groove GR2, the adhesive strength of the first encapsulation inorganic film disposed between the block structures BS having the second-first width GRW21 may be relatively strengthened. Conversely, the adhesive strength of the first encapsulation inorganic film disposed between the block structures BS having the second-second width GRW22 may be relatively weakened.

In one embodiment, the block structure BS may be surrounded by the second groove having the second-first width GRW21 or the second-second width GRW22. The second-first width GRW21 may be smaller than the first width of the first groove. In some examples, the second-second width GRW22 may be smaller than or equal to the width of the first groove. In a subset of these examples, the second-second width GRW22 may be smaller than or equal to the width of each first groove where the first groove encompasses a plurality of first grooves. Any ranges that may be combined, united, or derived based on the present disclosure, such as the shape and width of the groove, and combinations thereof, are all included within the scope of the present disclosure.

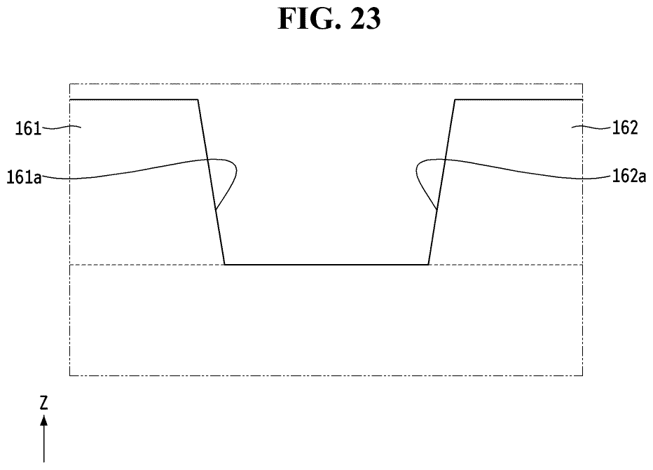

FIGS. 23 to 26 are cross-sectional views illustrating steps in a process of fixing a block structure in place in a display device according to an embodiment of the present disclosure.

In one step, referring to FIG. 23, the first-first organic film 161 and the first-second organic film 162 adjacent to the first-first organic film 161, each being a portion that protrudes from the first organic film, may be disposed to be spaced apart from each other. Since there is no external force in the lower region between the first-first organic film 161 and the first-second organic film 162, the first organic film disposed between the first-first organic film 161 and the first-second organic film 162 may have a flat surface.

At this time, the separation distance between the first-first organic film 161 and the first-second organic film 162 may be, in some examples, in a range from 0.1 μm to 10 μm. In a subset of these examples, the separation distance may be in a range from about 0.1 μm to about 8 μm. When the separation distance between the first-first organic film 161 and the first-second organic film 162 is not within the above-described range, a horizontal force due to the compressive stress between the inorganic materials laminated between the first-first organic film 161 and the first-second organic film 162 is not generated, and in this way, there is an absence of an external force that would otherwise act in the lower regions of the first-first organic film 161 and the first-second organic film 162. Without the external force, a top surface of the first organic film disposed between the first-first organic film 161 and the first-second organic film 162 remains unchanged and in a flat state. However, in this case as well, a repulsive force or the like acts, so that the adhesive strength of the first encapsulation inorganic film may still be relatively high.

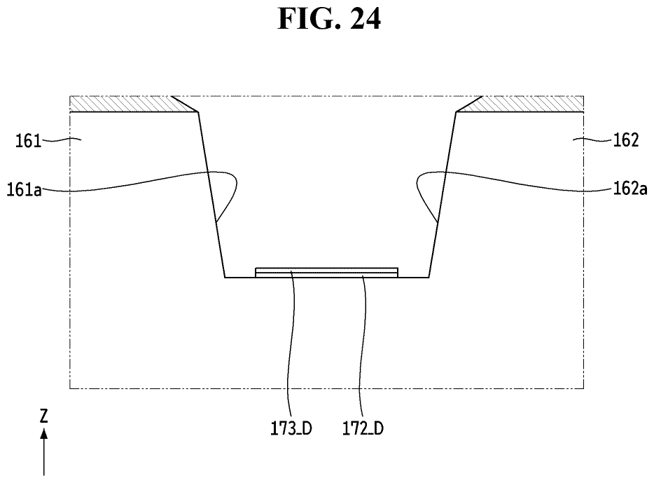

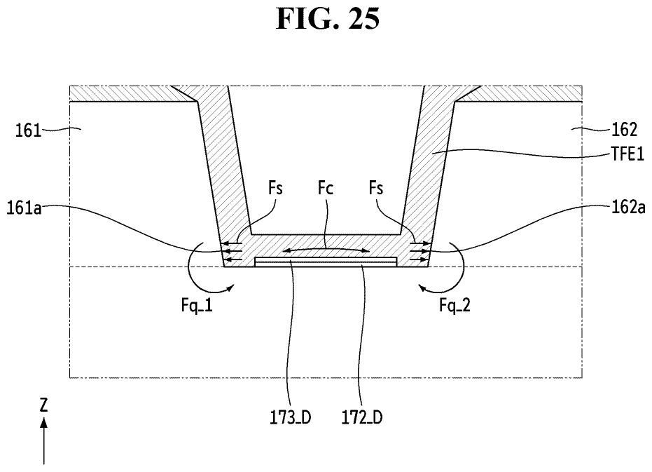

In a subsequent step, referring to FIGS. 24 and 25, in one embodiment, after the remnants 172_D and 173_D are formed on the top surfaces of the first-first organic film 161, the first-second organic film 162, and the first organic film disposed between the first-first organic film 161 and the first-second organic film 162, the first encapsulation inorganic film TFE1 is deposited on the remnants 172_D and 173_D by a chemical vapor deposition (CVD) method. In this step, the first encapsulation inorganic film TFE1 is formed to be conformal to the surface shape of the remnants 172_D and 173_D with a small thickness.

The first encapsulation inorganic film TFE1 deposited on the remnants 172_D and 173_D has a compressive stress when disposed, and preferably has a compressive stress value in a range from about −500 MPa to just under 0 MPa. At this time, the compressive stress acts as a force in a direction that pushes the first encapsulation inorganic film TFE1 in opposite directions along a portion of the first encapsulation inorganic film TFE1 between organic films 161, 162, and includes the force Fc in a direction of bending the first encapsulation inorganic film TFE1 downward.

When the compressive stress acts in this way, a force that horizontally pushes as much as possible is generated between inorganic materials, and this includes a repulsive force Fs that pushes the lower regions of the first-first organic film 161 and the first-second organic film 162, that is, the lower regions of the opposing inclined surfaces of the first-first organic film 161 and the first-second organic film 162, in the horizontal direction. The repulsive force Fs may be generated by the horizontal pushing force Fc at opposite edges of the first encapsulation inorganic film TFE1 deposited on the remnants 172_D and 173_D and may act in opposing directions.

In this way, and as shown in FIG. 25, when the repulsive force Fs is generated that horizontally pushes the lower regions of the opposing inclined surfaces of the first-first organic film 161 and the first-second organic film 162, a counterclockwise torque Fq_1 may be generated in the lower region of the first-first organic film 161, and a clockwise torque Fq_2 may be generated in the lower region of the first-second organic film 162.

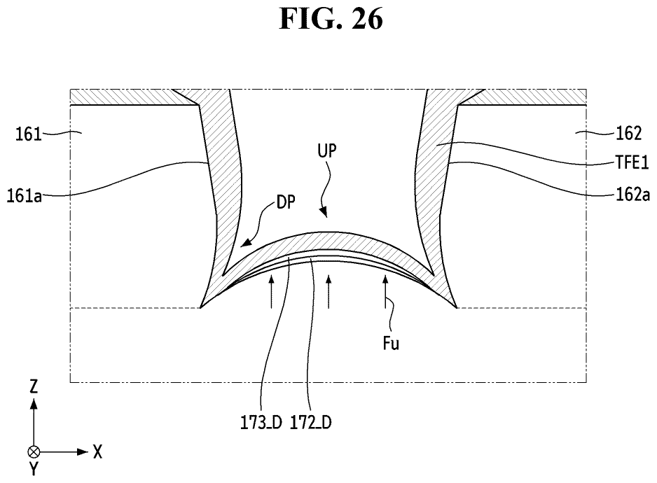

In a subsequent step, referring to FIG. 26, the counterclockwise torque Fq_1 generated in the lower region of the first-first organic film 161 and the clockwise torque Fq_2 generated in the lower region of the first-second organic film 162 may act as a force Fu that uplifts the central portion of the top surface of the first organic film disposed between the first-first organic film 161 and the first-second organic film 162 in the thickness direction while overlapping the central portion of the top surface of the first organic film disposed between the first-first organic film 161 and the first-second organic film 162. Accordingly, through the generation of these forces, the uplift portion UP may be formed.

The uplift portion UP thus formed, the depressed portion DP, and the shear force may contribute to the improvement of the adhesive strength between the first encapsulation inorganic film TFE1 and the remnants 172_D and 173_D along with the adhesive strength between the first encapsulation inorganic film TFE1 and the second encapsulation inorganic film (not shown), as described above.

The display device according to the embodiments contemplated by the present disclosure may be applied to various electronic devices. The electronic device according to one embodiment may include any one of the display devices described above or otherwise contemplated, and may further include a module or device having an additional function in addition to the display device.

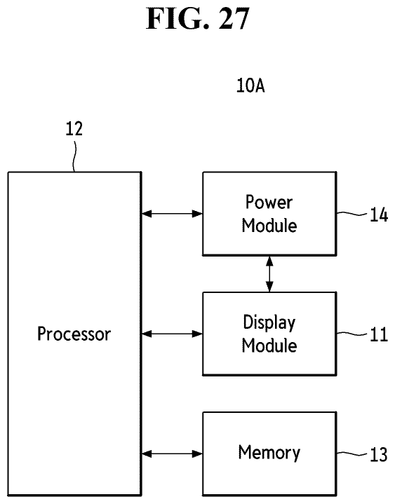

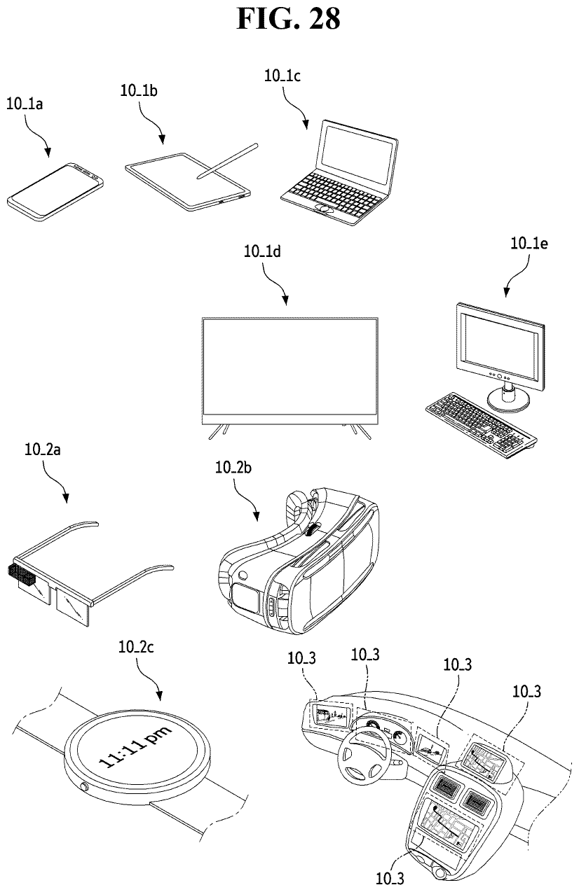

FIG. 27 is a block diagram of an electronic device according to one embodiment of the present disclosure. FIG. 28 includes schematic views of various electronic devices according to respective embodiments of the present disclosure.

Referring to FIG. 27, an electronic device 10A according to some embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information required for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module such as a power adapter or a battery device. The power module 14 may include a power conversion module. The power conversion module may convert the power supplied by the power supply module to generate power required for the operation of the electronic device 10A.

At least one of the components of the electronic device 10A described above may be included in the display device according to the embodiments described above. Further, some of individual modules functionally included in one module may be included in the display device and some others may be provided separately from the display device. For example, the display device may include the display module 11, and the processor 12, while the memory 13, and the power module 14 may be provided in the form of other devices in the electronic device 10A other than the display device.

Referring to FIG. 28, various electronic devices to which the display device according to the embodiments of the present disclosure may be applied to include electronic devices for displaying images, such as a smartphone 10_1a, a tablet PC 10_1b, a laptop 10_1c, a television (TV) 10_1d, a desk monitor 10_1e, and the like. In addition, various electronic devices to which the display device according to the embodiments of the present disclosure may be applied include a wearable electronic device including a display module, such as smart glasses 10_2a, a head mounted display 10_2b, a smart watch 10_2c, or the like, a vehicle electronic device 10A_3 including a display module, such as a center information display (CID) placed on a dashboard, a center fascia, and an instrument panel of a car, and a room mirror display, or the like.

Although embodiments of the disclosure have been described above with reference to the accompanying drawings, it will be understood by those having ordinary skill in the technical field to which the disclosure belongs that the disclosure may be practiced in other specific forms without altering the technical idea or essential features of the disclosure. It should therefore be understood that the embodiments described above are exemplary in all respects and are not intended to be limiting.

What is claimed is:

1. A display device comprising:
a substrate;
a plurality of pixels disposed on the substrate in a display area;
a through hole penetrating the substrate;
a plurality of first grooves surrounding the through hole;
a plurality of block structures disposed between the plurality of first grooves and the through hole; and
a second groove surrounding the plurality of block structures.

2. The display device of claim 1, wherein each pixel of the plurality of pixels comprises:
a first electrode;
a light emitting layer disposed on the first electrode; and
a second electrode disposed on the light emitting layer, and
the second groove further comprises:
a first remnant, the first remnant and the light emitting layer both containing a first material; and
a second remnant disposed on the first remnant, the second remnant and the second electrode both containing a second material.

3. The display device of claim 2, wherein the second groove further comprises an encapsulation layer disposed on the second remnant.

4. The display device of claim 3, wherein the encapsulation layer further comprises an inorganic film.

5. The display device of claim 1, further comprising a first organic film disposed on the substrate,
wherein the plurality of block structures are disposed on the first organic film and further comprise a first block structure and a second block structure adjacent to each other along one direction.

6. The display device of claim 5, wherein the first block structure further comprises a first sub-block structure and a second sub-block structure disposed on the first sub-block structure.

7. The display device of claim 5, wherein the second groove is in between the first block structure and the second block structure and
the second groove further comprises:
a pair of opposing inclined surfaces; and
an uplift portion in between the pair of opposing inclined surfaces, the uplift portion having a convex curved portion, a convex surface of the convex curved portion facing an open space defined by the second groove.

8. The display device of claim 5, wherein the second groove further comprises an encapsulation layer including an encapsulation inorganic film, and
a modulus of elasticity of the encapsulation inorganic film is greater than a modulus of elasticity of the first block structure and a modulus of elasticity of the second block structure.

9. The display device of claim 1, wherein in a plan view of the substrate, each first groove of the plurality of first grooves has a closed shape, the closed shape being curved.

10. An electronic device comprising:
a display device; and
a power module configured to supply power to the display device,
wherein the display device comprises:
a substrate;
a plurality of pixels disposed on the substrate in a display area;
a through hole penetrating the substrate;
a plurality of first grooves surrounding the through hole;
a plurality of block structures disposed between the plurality of first grooves and the through hole; and
a second groove surrounding the plurality of block structures.

11. A display device comprising:
a substrate;
a plurality of pixels disposed on the substrate in a display area;
a through hole penetrating the substrate;
a first groove surrounding the through hole, the first groove being arranged between a first dam and a second dam and having a first width;
a plurality of block structures disposed between the first groove and the through hole, the plurality of block structures including a first block structure and a second block structure; and
a second groove arranged between the first block structure and the second block structure and having a second width,
wherein the first width is greater than the second width.

12. The display device of claim 11, wherein each pixel of the plurality of pixels comprises:
a first electrode;
a light emitting layer disposed on the first electrode; and
a second electrode disposed on the light emitting layer, and
the second groove further comprises:
a first remnant, the first remnant and the light emitting layer both containing a first material; and
a second remnant disposed on the first remnant, the second remnant and the second electrode both containing a second material.

13. The display device of claim 12, wherein the second groove further comprises an encapsulation layer disposed on the second remnant.

14. The display device of claim 13, wherein the encapsulation layer further comprises an inorganic film.

15. The display device of claim 11, further comprising a first organic film disposed on the substrate,
wherein the plurality of block structures are disposed on the first organic film and further comprise a first block structure and a second block structure adjacent to each other along one direction.

16. The display device of claim 15, wherein the first block structure further comprises a first sub-block structure and a second sub-block structure disposed on the first sub-block structure.

17. The display device of claim 15, wherein the second groove is in between the first block structure and the second block structure and
the second groove further comprises:
a pair of opposing inclined surfaces; and
an uplift portion in between the pair of opposing inclined surfaces, the uplift portion having a convex curved portion, a convex surface of the convex curved portion facing an open space defined by the second groove.

18. The display device of claim 15, wherein the second groove further comprises an encapsulation layer including an encapsulation inorganic film, and
a modulus of elasticity of the encapsulation inorganic film is greater than a modulus of elasticity of the first block structure and a modulus of elasticity of the second block structure.

19. The display device of claim 11, wherein in a plan view of the substrate, the first groove has a closed shape, the closed shape being curved.

20. The display device of claim 1, wherein the second groove is one of a plurality of second grooves, the plurality of second grooves being arranged such that two or more second grooves of the plurality of grooves surround each block structure of the plurality of block structures.
